(19) United States
(12) Patent Application Publication
(10) Pub. No.: US 2022/0013598 A1
(43) Pub. Date: Jan. 13, 2022

(54) DISPLAY DEVICE

(71) Applicant: LG Display Co., Ltd., Seoul (KR)

(72) Inventors: Sung Jin PARK, Paju-si (KR); Juhn Suk YOO, Paju-si (KR); Min Ha KANG, Paju-si (KR); Yu Hoon KIM, Paju-si (KR)

(21) Appl. No.: 17/368,206

(22) Filed: Jul. 6, 2021

Related U.S. Application Data
(60) Provisional application No. 63/049,868, filed on Jul. 9, 2020.

(51) Int. Cl. H01L 27/32

(52) U.S. Cl. CPC H01L 27/3218; H01L 27/3234; H01L 27/3216; H01L 27/3213

(57) ABSTRACT

A display device includes a first display area including a plurality of first pixel groups, and a second display area including a plurality of second pixel groups and a plurality of light-transmitting areas. Each of the plurality of second pixel groups includes a plurality of sub-pixels, and in any one sub-pixel of the plurality of sub-pixels, a light-emitting element is disposed in a light-transmitting area from the plurality of light-transmitting areas that corresponds to the any one sub-pixel.

### CROSS-REFERENCE TO RELATED APPLICATION

This application claims priority to and the benefit of U.S. Provisional Patent Application No. 63/049,868, filed on Jul. 9, 2020, the disclosure of which is hereby incorporated by reference in its entirety.

### BACKGROUND

### 1. Field of Technology

The embodiments herein relate to a display device.

### 2. Discussion of Related Art

Electroluminescence display devices are classified into inorganic light-emitting display devices or organic light-emitting display devices depending on materials of a light-emitting layer. An active-matrix-type organic light-emitting display device includes an organic light-emitting diode (OLED) that emits light by itself and has advantages in terms of a quick response time, high luminous efficiency, high luminance, and a wide viewing angle. The organic light-emitting display device has an OLED formed in each pixel. The organic light-emitting display device may express a black grayscale as perfect black as well as having a quick response time, high luminous efficiency, high luminance, and a wide viewing angle, and thus has an excellent contrast ratio and color gamut.

Recently, multimedia functions of a mobile terminal have been improved. For example, a camera is built in a mobile terminal and the resolution of the camera is increasing to a level of existing digital cameras. However, a front camera of the mobile terminal limits the design of a screen, thereby making it difficult to design the screen. In order to reduce the space occupied by the camera, a screen design including a notch or a punch hole has been adopted in the mobile terminal, but it is difficult to implement a full-screen display because a screen size is still limited due to the camera.

### SUMMARY

In order to implement a full-screen display, a method of preparing an imaging area in which low-resolution pixels are disposed in a screen of a display panel, and disposing a camera and/or various sensors in the imaging area, is proposed.

Embodiment are directed to providing a display device allowing the quality of a picture in an imaging area (an under display camera (UDC) area), in which a camera module is disposed, to be improved.

It should be noted that objects of the present disclosure are not limited to the above-described object, and other objects of the present disclosure will be apparent to those skilled in the art from the following descriptions.

According to an aspect of the present disclosure, there is provided a display device including a first display area including a plurality of first pixel groups, and a second display area including a plurality of second pixel groups and a plurality of light-transmitting areas. Each of the plurality of second pixel groups includes a plurality of sub-pixels. And in any one sub-pixel of the plurality of sub-pixels, a light-emitting element is disposed in a light-transmitting area from the plurality of light-transmitting areas that corresponds to the any one sub-pixel.

The second display area may include a first pixel row in which the plurality of second pixel groups are continuously disposed in a first direction, and a second pixel row in which the plurality of light-transmitting areas are continuously disposed in the first direction. The first pixel row and the second pixel row may be alternately disposed in a second direction intersecting the first direction.

The plurality of sub-pixels may include a first sub-pixel including a first light-emitting element, a second sub-pixel including a second light-emitting element, a third sub-pixel including a third light-emitting element, and a fourth sub-pixel including a fourth light-emitting element. A partial area of at least one of the second light-emitting element and the fourth light-emitting element may be disposed in the light-transmitting area.

The second light-emitting element and the fourth light-emitting element may be green light-emitting elements.

A first imaginary line connecting a center of each of the second light-emitting element and the fourth light-emitting element may intersect the first direction and the second direction.

Each of the plurality of first pixel groups may include a first green light-emitting element and a second green light-emitting element. An imaginary line connecting a center of each of the first green light-emitting element and the second green light-emitting element may be parallel to the first direction.

Based on a second imaginary line passing through a center of each of the first light-emitting element and the third light-emitting element, the second light-emitting element may be disposed on one side of the second imaginary line, and the fourth light-emitting element may be disposed on another side of the second imaginary line.

The first light-emitting element to the fourth light-emitting element of the plurality of second pixel groups may have a structure in which light-emitting elements of a same color are disposed in a quadrangular shape.

Fourth light-emitting elements of the plurality of second pixel groups may be disposed along each of a plurality of quadrangular-shaped lines, and the first light-emitting element, the second light-emitting element, and the third light-emitting element may be disposed inside each of the plurality of quadrangular-shaped lines.

A resolution of the second display area may be less than a resolution of the first display area.

The display device includes lines disposed in the first display area and the second display area. The lines may be disposed to bypass the light-transmitting areas.

The display device may include a cathode disposed in the first display area and the second display area. The cathode may include an opening corresponding to the plurality of light-transmitting area.

A shape of light-emitting elements of the first pixel group may be different from a shape of light-emitting elements of the second pixel group.

According to another aspect of the present disclosure, there is provided a display device including a first display area including a plurality of first pixel groups, and a second display area including a plurality of second pixel groups and a plurality of light-transmitting areas. The plurality of second pixel groups include a plurality of sub-pixels. The plurality of second pixel groups include a first light-emitting element configured to emit red light, a third light-emitting element configured to emit blue light, and a second light-emitting element and a fourth light-emitting element configured to emit green light, and a first imaginary line connecting a center of each of the second light-emitting element and the fourth light-emitting element intersects a second imaginary line connecting a center of each of the first light-emitting element and the third light-emitting element.

Based on the second imaginary line, the second light-emitting element may be disposed on one side of the second imaginary line, and the fourth light-emitting element may be disposed on another side of the second imaginary line.

The second display area may include a first pixel row in which the plurality of second pixel groups are continuously disposed, and a second pixel row in which the plurality of light-transmitting areas are continuously disposed.

A portion of at least one of the second light-emitting element and the fourth light-emitting element may be disposed in the light-transmitting area.

A number of the plurality of second pixel groups disposed in the second display area may be less than a number of the plurality of first pixel groups disposed in the first display area.

According to still another aspect of the present disclosure, there is provided a display device including a first display area including a plurality of first pixel groups, and a second display area including a plurality of second pixel groups and a plurality of light-transmitting areas. The second display area includes a first unit area having less pixels than the first display area and a second unit area having less pixels than the first unit area.

An image sensor may be disposed in the first unit area, and an infrared sensor may be disposed in the second unit area.

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a conceptual diagram of a display device according to one embodiment of the present disclosure;

FIGS. 2A to 2D are views illustrating various arrangement positions and shapes of a second display area according to one embodiment of the present disclosure;

FIG. 3 is a schematic cross-sectional view illustrating a display panel according to one embodiment of the present disclosure;

FIG. 4 is a view illustrating a pixel arrangement in a first display area according to one embodiment of the present disclosure;

FIG. 5 is a view illustrating pixels and light-transmitting areas of a second display area according to one embodiment of the present disclosure;

FIG. 6 is a schematic view illustrating a structure of the display panel of the second display area according to one embodiment of the present disclosure;

FIG. 7 is a modified example of FIG. 6 according to one embodiment of the present disclosure;

FIG. 8 is a view illustrating a pixel arrangement in a second display area according to a first embodiment of the present disclosure;

FIG. 9 is a partially enlarged view of FIG. 8 according to one embodiment of the present disclosure;

FIG. 10 is a view illustrating a pixel arrangement in a second display area according to a second embodiment of the present disclosure;

FIG. 11A is a partially enlarged view of FIG. 10 according to second embodiment of the present disclosure;

FIG. 11B is a modified example of FIG. 11A according to second embodiment of the present disclosure;

FIG. 12 is a view illustrating a pixel arrangement in a second display area according to a third embodiment of the present disclosure;

FIG. 13 is a first comparative example illustrating a pixel arrangement in a second display area according to one embodiment;

FIG. 14 illustrates a result of observing whether patterns are recognized from the outside according to one embodiment;

FIG. 15 is a second comparative example illustrating a pixel arrangement in a second display area according to one embodiment;

FIG. 16 is a view illustrating a pixel arrangement in a second display area according to a fourth embodiment of the present disclosure;

FIG. 17 is a view illustrating a pixel arrangement in a second display area according to a fifth embodiment of the present disclosure;

FIG. 18 is a view illustrating a pixel arrangement in a second display area according to a sixth embodiment of the present disclosure;

FIG. 19 is a view illustrating a pixel arrangement in a second display area according to a seventh embodiment of the present disclosure;

FIG. 20 is a view illustrating a pixel arrangement in a second display area according to an eighth embodiment of the present disclosure;

FIG. 21 is an enlarged view of FIG. 20 according to the eighth embodiment of the present disclosure;

FIG. 22 is a modified example of FIG. 21 according to one embodiment of the present disclosure;

FIG. 23 is a second modified example of FIG. 21 according to one embodiment of the present disclosure;

FIG. 24A is a view illustrating a pixel arrangement in a second display area according to a ninth embodiment of the present disclosure;

FIG. 24B is a view illustrating a structure in which an area of a light-transmitting area varies in a second display area according to one embodiment of the present disclosure;

FIG. 25 is a view illustrating a pixel arrangement in a second display area according to a tenth embodiment of the present disclosure;

FIG. 26 is an enlarged view of FIG. 25 according to the tenth embodiment of the present disclosure;

FIG. 27 is a view illustrating a pixel arrangement in a second display area according to an eleventh embodiment of the present disclosure;

FIG. 28 is a view illustrating a pixel arrangement in a second display area according to a twelfth embodiment of the present disclosure;

FIG. 29 is a view illustrating a pixel arrangement in a second display area according to a thirteenth embodiment of the present disclosure;

FIG. 30 is a view illustrating a pixel arrangement in a second display area according to a fourteenth embodiment of the present disclosure;

FIG. 31 is a view illustrating a pixel arrangement in a second display area according to a fifteenth embodiment of the present disclosure;

FIG. 32 is a view illustrating a pixel arrangement in a second display area according to a sixteenth embodiment of the present disclosure;

FIG. 33 is a view illustrating a pixel arrangement in a second display area according to a seventeenth embodiment of the present disclosure;

FIG. 34 is a block diagram illustrating a display panel and a display panel driving unit according to an embodiment of the present disclosure;

FIG. 35 is a schematic block diagram illustrating a configuration of a driver integrated circuit (IC) according to one embodiment of the present disclosure;

FIG. 36 is a circuit diagram illustrating an example of a pixel circuit according to one embodiment of the present disclosure;

FIG. 37 is a circuit diagram illustrating another example of the pixel circuit according to one embodiment of the present disclosure;

FIG. 38 is a view illustrating a method of driving the pixel circuit according to one embodiment of the present disclosure;

FIG. 39 is a cross-sectional view illustrating a cross-sectional structure of a pixel area in detail in a display panel according to one embodiment of the present disclosure;

FIG. 40 illustrates a cross-sectional structure of the pixel area and the light-transmitting area of the second display area according to one embodiment of the present disclosure; and

FIG. 41 is a view illustrating a data voltage applied to pixels of the first display area and a data voltage applied to pixels of the second display area according to one embodiment of the present disclosure.

### DETAILED DESCRIPTION

Advantages and features of the present disclosure and implementation methods thereof will be clarified through the following embodiments described with reference to the accompanying drawings. However, the present disclosure is not limited to the embodiments described below and may be implemented with a variety of different forms. The embodiments are merely provided to allow those skilled in the art to completely understand the scope of the present disclosure, and the present disclosure is defined only by the scope of the claims.

The figures, dimensions, ratios, angles, numbers, and the like disclosed in the drawings for describing the embodiments of the present disclosure are merely illustrative and are not limited to details shown in the present disclosure. Like reference numerals refer to like elements throughout. Further, in describing the present disclosure, detailed descriptions of well-known technologies will be omitted when it is determined that they may unnecessarily obscure the gist of the present disclosure.

Terms such as “including,” “having,” and “composed of” used herein are intended to allow other elements to be added unless the terms are used with the term “only.” Any references to the singular may include the plural unless expressly stated otherwise.

Components are interpreted as including an ordinary error range even if not expressly stated.

For description of a positional relationship, for example, when the positional relationship between two parts is described as “on,” “above,” “below,” and “next to,” etc., one or more parts may be interposed therebetween unless the term “immediately” or “directly” is used in the expression.

In the description of embodiments, the terms “first,” “second,” and the like may be used herein to describe various components, the components are not limited by the terms. These terms are used only to distinguish one component from another. Therefore, a first component discussed below could be termed a second component without departing from the teachings of the present disclosure.

Like reference numerals refer to like elements throughout.

The features of various embodiments may be partially or entirely combined with each other. The embodiments may be interoperated and performed in technically various ways and may be carried out independently of or in association with each other.

Hereinafter, various embodiments of the present disclosure will be described in detail with reference to the accompanying drawings.

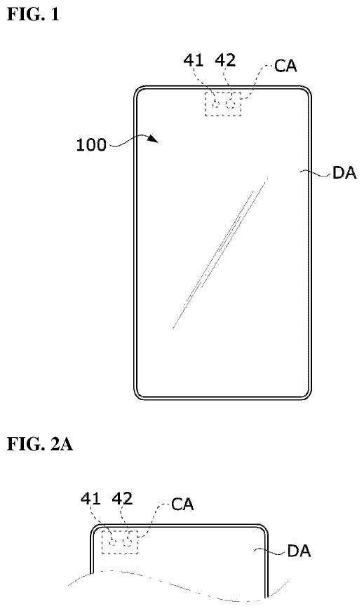

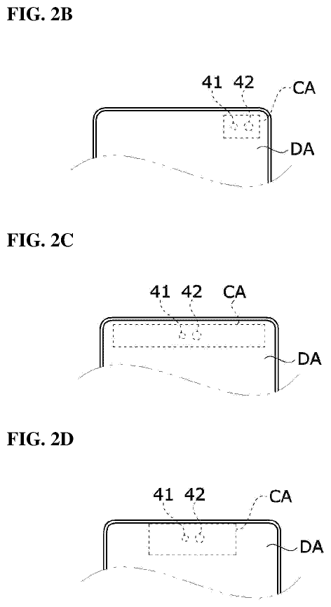

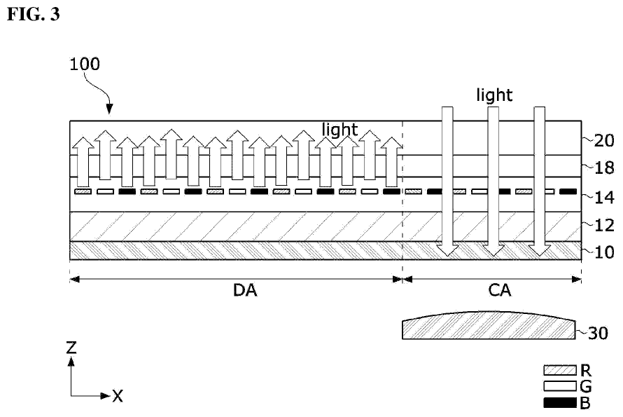

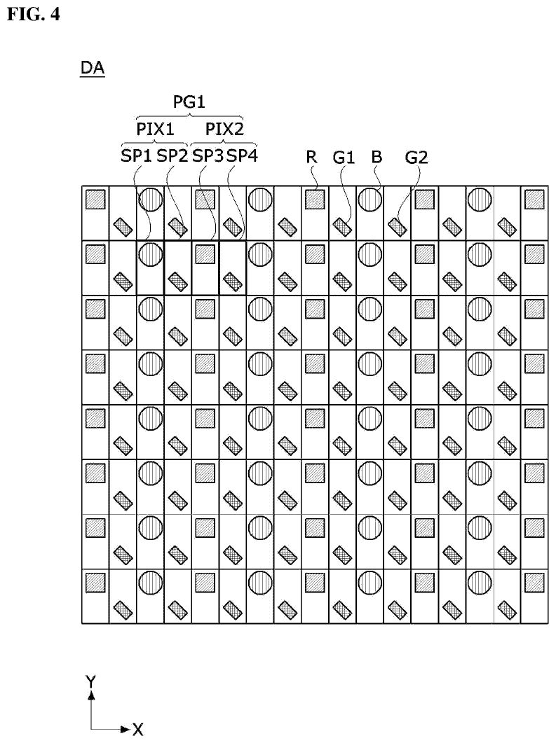

FIG. 1 is a conceptual diagram of a display device according to one embodiment of the present disclosure, FIGS. 2A to 2D are views illustrating various arrangement positions and shapes of a second display area according to one embodiment of the present disclosure, FIG. 3 is a schematic cross-sectional view illustrating a display panel according to the embodiment of the present disclosure, and FIG. 4 is a view illustrating a pixel arrangement of a first display area according to one embodiment of the present disclosure.

Referring to FIG. 1, a display panel 100 and a case may be included, and an entire surface of the display panel 100 may be formed as a display area. Thus, a full-screen display may be implemented.

The display area may include a first display area DA and a second display area CA. The first display area DA and the second display area CA may both output an image, but the resolution may differ between the first display area DA and the second display area CA. As an example, a resolution of a plurality of second pixels disposed in the second display area CA may be less than a resolution of a plurality of first pixels disposed in the first display area DA. A sufficient amount of light may be injected into sensors 41 and 42 disposed in the second display area CA by as much as the resolution lowered in the plurality of second pixels disposed in the second display area CA.

However, the present disclosure is not limited thereto, and the resolution of the first display area DA and the resolution of the second display area CA may be the same as long as the second display area CA may have sufficient light transmittance or an appropriate compensation algorithm may be implemented.

The second display area CA may be an area in which the sensors 41 and 42 are disposed. The second display area CA is an area that overlaps various sensors and thus may be smaller than the area of the first display area DA outputting most of the image. The second display area CA may be an imaging area in which various sensors collect information.

The sensors 41 and 42 may include at least one of an image sensor, a proximity sensor, an illumination sensor, a gesture sensor, a motion sensor, a fingerprint recognition sensor, or a biometric sensor. As an example, a first sensor 41 may be an illumination sensor or an infrared sensor and a second sensor 42 may be an image sensor configured to capture an image or a video, but the present disclosure is not necessarily limited thereto.

Referring to FIGS. 2A to 2D, the second display area CA may be disposed at various positions where light needs to be incident. As an example, the second display area CA may be disposed at an upper left end of the display area as shown in FIG. 2A, the second display area CA may be disposed at an upper right end of the display area as shown in FIG. 2B, the second display area CA may be disposed at an entire upper end of the display area as shown in FIG. 2C, and a width of the second display area CA may be variously modified as shown in FIG. 2D. However, the present disclosure is not necessarily limited thereto, and the second display area CA may be disposed at a central portion of the first display area DA or disposed at a lower end of the display area.

Referring to FIGS. 3 and 4, the first display area DA and the second display area CA may include a pixel array in which pixels, to which pixel data is written, are disposed. The number of pixels per unit area (hereinafter, referred to as “pixels per inch (PPI)”) of the second display area CA may be lower than that of the first display area DA in order to ensure the light transmittance of the second display area CA.

The pixel array of the first display area DA may include a pixel area in which a plurality of pixel groups having a high PPI are disposed. The pixel array of the second display area CA may include a pixel area in which a plurality of pixel groups having a relatively low PPI are disposed by being spaced apart from each other by light-transmitting areas. In the second display area CA, external light may pass through the display panel 100 through the light-transmitting areas having high light transmittance and may be received by a sensor placed below the display panel 100.

Since both the first display area DA and the second display area CA include the pixels, an input image may be reproduced on the first display area DA and the second display area CA. Thus, a full-screen display may be implemented.

Each of the pixels of the first display area DA and the second display area CA may include sub-pixels having different colors to implement a color of an image. The sub-pixels may include red, green, and blue sub-pixels. Although not shown in the drawings, the pixel group may further include a white sub-pixel. Each of the sub-pixels may include a pixel circuit part and a light-emitting element (organic light-emitting diode: OLED).

The second display area CA may include the pixels and a camera module disposed below a screen of the display panel 100. The camera module may include an image sensor. The pixels of the second display area CA may display an input image by writing pixel data of an input image in a display mode.

The camera module may capture an external image in an imaging mode to output a picture or video image data. A lens 30 of the camera module may face the second display area CA. The external light is incident on the lens 30 of the camera module through the second display area CA, and the lens 30 may condense light to an image sensor that is omitted from the drawing. The camera module may capture the external image in the imaging mode to output a picture or video image data.

In order to ensure light transmittance, due to pixels being removed from the second display area CA, an image quality compensation algorithm for compensating luminance and color coordinates of the pixels in the second display area CA may be applied.

The display panel 100 may have a width in an X-axis direction, a length in a Y-axis direction, and a thickness in a Z-axis direction. The display panel 100 may include a circuit layer 12 disposed on a substrate 10, and a light-emitting element layer 14 disposed on the circuit layer 12. A polarizing plate 18 may be disposed on the light-emitting element layer 14, and a cover glass 20 may be disposed on the polarizing plate 18.

The circuit layer 12 may include a pixel circuit connected to lines such as data lines, gate lines, power lines, and the like, a gate driving unit connected to the gate lines, and the like.

The circuit layer 12 may include a circuit element such as a transistor implemented as a thin-film transistor (TFT), a capacitor, and the like. The lines and circuit elements of the circuit layer 12 may be implemented with a plurality of insulating layers, two or more metal layers separated from each other with the insulating layers therebetween, and an active layer including a semiconductor material.

The light-emitting element layer 14 may include the light-emitting element driven by the pixel circuit. The light-emitting element may be implemented as an OLED. The OLED may include an organic compound layer formed between an anode and a cathode.

The organic compound layer may include a hole injection layer HIL, a hole transport layer HTL, an emission layer EML, an electron transport layer ETL, and an electron injection layer EIL, but the present disclosure is not limited thereto.

When a voltage is applied to the anode and the cathode of the OLED, holes passing through the hole transport layer HTL and electrons passing through the electron transport layer ETL move to the emission layer EML to create excitons, and thus visible light may be emitted from the emission layer EML.

The light-emitting element layer 14 may further include a color filter array disposed on the pixels that selectively transmit light of red, green, and blue wavelengths.

The light-emitting element layer 14 may be covered by a protective film, and the protective film may be covered by an encapsulation layer. The protective film and the encapsulation layer may have a structure in which organic films and inorganic films are alternately stacked. The inorganic films may block the penetration of moisture or oxygen. The organic films may planarize a surface of the inorganic film. When the organic films and the inorganic films are stacked in multiple layers, the penetration of moisture/oxygen affecting the light-emitting element layer 14 may be effectively blocked since a movement path of the moisture or oxygen is increased in length as compared with a single layer.

The polarizing plate 18 may be disposed on the encapsulation layer. The polarizing plate 18 can improve outdoor visibility of the display device. The polarizing plate 18 may reduce the reflection of light from a surface of the display panel 100 and block the light reflected from metal of the circuit layer 12, thereby improving the brightness of the pixels. The polarizing plate 18 may be implemented as a polarizing plate to which a linear polarizing plate and a phase retardation film are bonded, or a circular polarizing plate.

Referring to FIG. 4, the first display area DA may include a plurality of first pixel groups PG1 arranged in a matrix form. In the plurality of first pixel groups PG1, two sub-pixels may form one pixel using a sub-pixel rendering algorithm. For example, a first unit pixel PIX1 may include R and G1 sub-pixels SP1 and SP2, and a second unit pixel PIX2 may include B and G2 sub-pixels SP3 and SP4. Insufficient color representation in each of the unit pixels PIX1 and PIX2 may be compensated with an average value of pieces of corresponding color data between neighboring pixels. However, the present disclosure is not necessarily limited thereto, and the plurality of first pixel groups PG1 may be real-type pixels including R, G, and B sub-pixels.

Each of the plurality of first pixel groups PG1 may include a red light-emitting element R, a first green light-emitting element G1, a blue light-emitting element B, and a second green light-emitting element G2. Here, an imaginary line connecting a center of each of the first green light-emitting element G1 and the second green light-emitting element G2 in each of the first pixel groups PG1 may be parallel to a first direction.

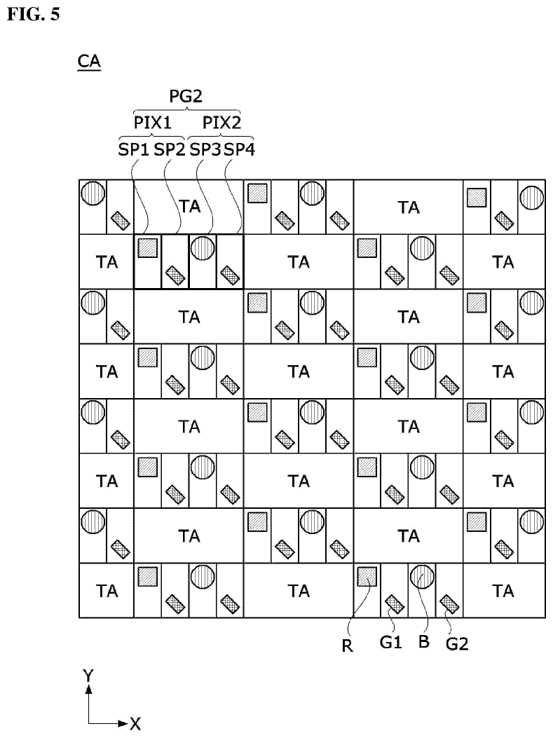

FIG. 5 is a view illustrating pixels and light-transmitting areas of a second display area according to one embodiment of the present disclosure.

Referring to FIG. 5, a second display area CA may include a plurality of second pixel groups PG2 and a plurality of light-transmitting areas TA. The plurality of light-transmitting areas TA may be disposed between the plurality of second pixel groups PG2. Specifically, each of the light-transmitting areas TA and the second pixel groups PG2 may be alternately disposed in the first and second directions. External light may be received to the lens of the camera module through the light-transmitting areas TA. A resolution of the second display area CA may decrease relative to a resolution of the first display area DA by the extent to which an area of the light-transmitting area TA increases.

The light-transmitting area TA may include transparent media having high light transmittance without having metal so that light may be incident with minimum light loss. The light-transmitting area TA may be made of transparent insulating materials without including metal lines or pixels. As the light-transmitting area TA becomes larger, the light transmittance of the second display area CA may be higher.

Each of the plurality of second pixel groups PG2 may include one or two pixels. For example, in each of the second pixel groups PG2, a first unit pixel PIX1 may include R and G1 sub-pixels SP1 and SP2, and a second unit pixel PIX2 may include B and G2 sub-pixels SP3 and SP4. The shape and arrangement of pixels of the second pixel group PG2 may be the same as or different from those of the first pixel group PG1.

The shape of the light-transmitting area TA is illustrated as being a quadrangular shape, but the present disclosure is not limited thereto. For example, the light-transmitting area TA may be designed in various shapes such as a circular shape, an elliptical shape, a polygonal shape, or the like.

All metal electrode materials may be removed from the light-transmitting area TA. Accordingly, lines TS of the pixels may be disposed outside the light-transmitting area TA. Thus, light may be effectively incident through the light-transmitting area. However, the present disclosure is not necessarily limited thereto, and the metal electrode material may be present in a partial area of the light-transmitting area TA.

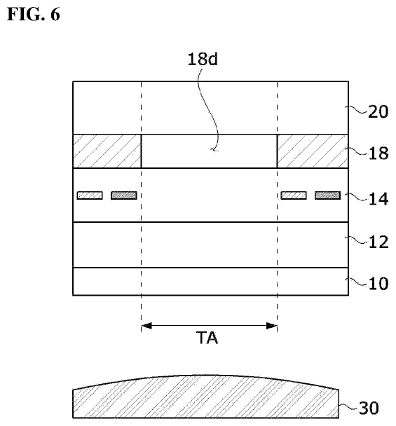

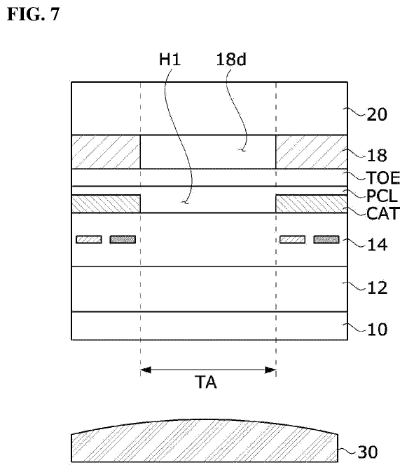

FIG. 6 is a schematic view illustrating a structure of the display panel of the second display area, and FIG. 7 is a modified example of FIG. 6 according to one embodiment.

Referring to FIG. 6, the display panel may include the circuit layer 12 disposed on the substrate 10, and the light-emitting element layer 14 disposed on the circuit layer 12. The polarizing plate 18 may be disposed on the light-emitting element layer 14, and the cover glass 20 may be disposed on the polarizing plate 18.

In the polarizing plate 18, a first light-transmitting pattern 18d may be formed in an area corresponding to the light-transmitting area TA. Based on green light having a wavelength of 555 nm, a light transmittance of the substrate made of PI is about 70% to 80%, and a light transmittance of the cathode is 80% to 90%. On the other hand, a light transmittance of the polarizing plate 18 is relatively very low, about 40%. Thus, in order to effectively increase the light transmittance in the light-transmitting area, it is necessary to increase the light transmittance of the polarizing plate 18.

The polarizing plate 18 according to the embodiment has the first light-transmitting pattern 18d formed above the light-transmitting area TA to improve light transmittance. The light transmittance of the area in which the first light-transmitting pattern is formed may be highest in the polarizing plate. Thus, the amount of light introduced into the camera module in the light-transmitting area increases, thereby improving camera performance.

The first light-transmitting pattern 18d of the polarizing plate 18 may be formed by removing a portion of the polarizing plate 18 and may also be formed by decomposing a compound constituting the polarizing plate 18. That is, the first light-transmitting pattern 18d may have various structures capable of increasing the light transmittance of the conventional polarizing plate 18.

Referring to FIG. 7, in the light-transmitting area TA, the polarizing plate 18 may have the first light-transmitting pattern 18d, and a cathode CAT may have a second light-transmitting pattern. The second light-transmitting pattern may be an opening H1 formed in the light-transmitting area TA. Since the light transmittance of the cathode is 80% to 90%, the light transmittance of the light-transmitting area TA may be further increased due to the opening H1.

A method of forming the opening H1 in the cathode CAT is not particularly limited. As an example, after the cathode is formed, the opening H1 may be formed in the cathode using an etching process, or the cathode may be removed using an infra-red (IR) laser at a lower portion of the substrate 10.

A planarization layer PCL may be formed on the cathode CAT, and a touch sensor TOE may be disposed on the planarization layer PCL. Here, in the light-transmitting area TA, a sensing electrode and lines of the touch sensor may be made of a transparent material such as indium tin oxide (ITO) or a metal mesh, thereby increasing light transmittance.

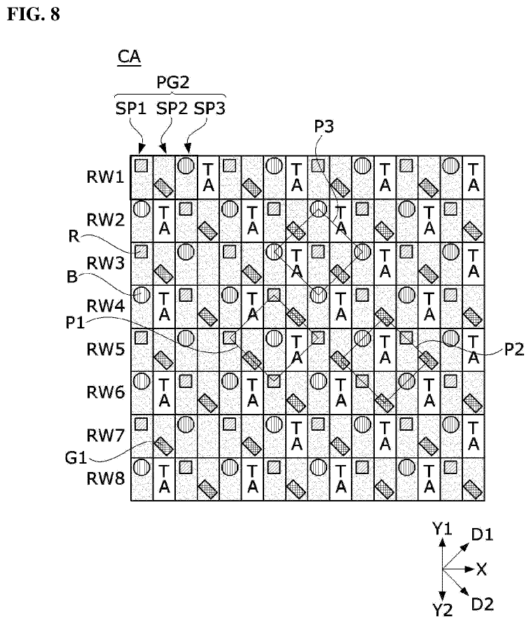

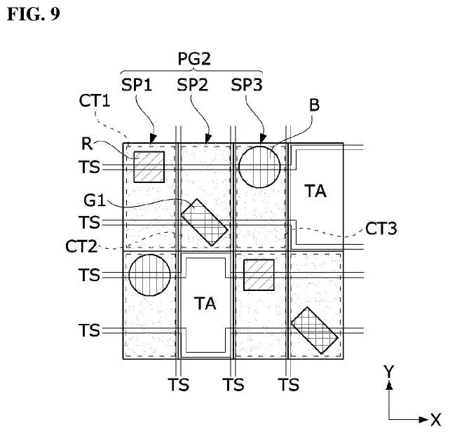

FIG. 8 is a view illustrating a pixel arrangement in a second display area according to a first embodiment of the present disclosure, and FIG. 9 is a partially enlarged view of FIG. 8 according to one embodiment.

Referring to FIGS. 8 and 9, a second display area CA may include a plurality of second pixel groups PG2 and a plurality of light-transmitting areas TA. The plurality of second pixel groups PG2 may be disposed in a plurality of pixel rows RW1 to RW8 and in a plurality of pixel columns in the first direction and the second direction. Hereinafter, the first direction may be an X-axis direction, and the second direction may be a Y1-axis or Y2-axis direction. Here, the pixel rows and the pixel columns may refer to rows and columns in which a plurality of sub-pixels are disposed, and the light-transmitting areas may be disposed in a partial area or all areas of the rows and the columns.

Each of the second pixel groups PG2 may include a first sub-pixel SP1, a second sub-pixel SP2, and a third sub-pixel SP3. The first sub-pixel SP1 may include a first light-emitting element R, the second sub-pixel SP2 may include a second light-emitting element G1, and the third sub-pixel SP3 may include a third light-emitting element B.

The first light-emitting element R may be a red light-emitting element, the second light-emitting element G1 may be a green light-emitting element, and the third light-emitting element B may be a blue light-emitting element, but the present disclosure is not necessarily limited thereto, and emission wavelengths may be variously modified.

According to the embodiment, the first to third sub-pixels SP1 to SP3 may be implemented as a real-type pixel constituting one pixel, but the present disclosure is not necessarily limited thereto. As an example, the second pixel group PG2 may further include a fourth sub-pixel, and the fourth sub-pixel may include a green light-emitting element or a white light-emitting element. Each light-emitting element may be an organic or inorganic light-emitting element.

The plurality of sub-pixels SP1, SP2, and SP3 may have a regular arrangement in the first direction or the second direction. The first sub-pixel SP1, the second sub-pixel SP2, and the third sub-pixel SP3 may be sequentially disposed in the first direction.

A width of the light-transmitting area TA may correspond to a width of each of the sub-pixels. According to such a structure, a large number of the light-transmitting areas TA may be disposed in a relatively small structure so that a uniform light-transmitting area may be secured. However, the present disclosure is not necessarily limited thereto, a size of the light-transmitting area may be variously adjusted. In addition, although the light-transmitting area is illustrated as having a quadrangular shape, a circular or polygonal shape may also be applied.

The first light-emitting elements R and the third light-emitting elements B may be alternately disposed in the first direction and the second direction. The second light-emitting element G1 may not overlap the first light-emitting element R and the third light-emitting element B in the first direction and the second direction.

The second light-emitting elements G1 and the third light-emitting elements B may be alternately disposed in a first diagonal direction D1, and the second light-emitting elements G1 and the first light-emitting elements R may be alternately disposed in a second diagonal direction D2. The first diagonal direction D1 may be a diagonal direction between a Y1-axis and an X-axis, and the second diagonal direction D2 may be a diagonal direction between a Y2-axis and the X-axis.

The first light-emitting elements R of the plurality of second pixel groups PG2 may be disposed on a first square-shaped line P1 that is inclined at 45°. In addition, the second light-emitting elements G1 may be disposed on a second square-shaped line P2, and the third light-emitting elements B may be disposed on a third square-shaped line P3. That is, each of the light-emitting elements may be disposed in a structure in which the light-emitting elements of the same color are disposed in a quadrangular shape.

According to the embodiment, since a center of each of the light-emitting elements (or a center of each of the sub-pixels) is disposed on the square-shaped line, a distance between the respective light-emitting elements becomes uniform, so that there is an advantage that relatively uniform image quality may be realized even when some pixels are omitted. In addition, a pixel pattern may not be observed from the outside, so that image quality may be improved.

Referring to FIG. 9, circuit parts CT1, CT2, and CT3 may be disposed in the sub-pixels SP1, SP2, and SP3, respectively. The circuit parts CT1, CT2, and CT3 may each include a pixel circuit connected to lines TS to drive the pixel.

The lines TS may be disposed to bypass the light-transmitting area TA. Here, the term “bypass” may mean that the lines TS are disposed so as to cover the light-transmitting area TA as little as possible. That is, the lines may be disposed in a part of the light-transmitting area. In addition, a portion of a cathode corresponding to the light-transmitting area TA may be patterned to increase light transmittance.

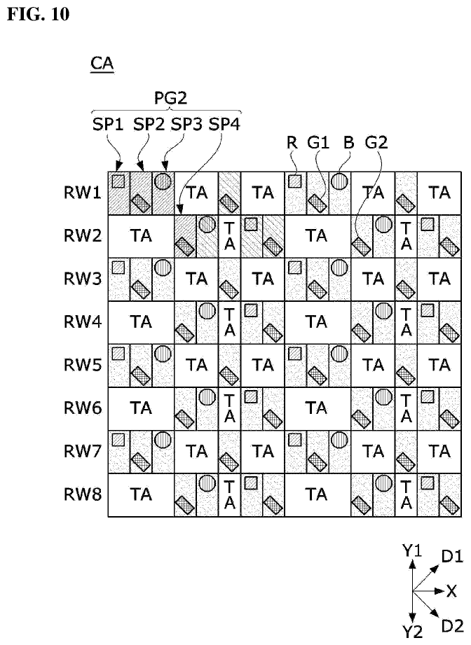

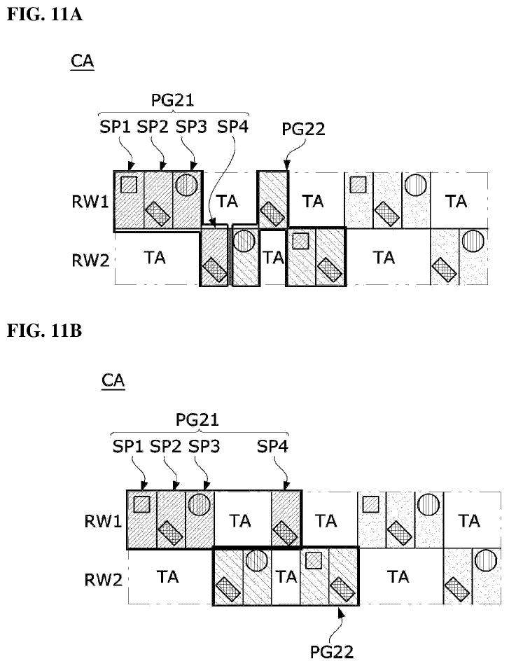

FIG. 10 is a view illustrating a pixel arrangement in a second display area according to a second embodiment of the present disclosure. FIG. 11A is a partially enlarged view of FIG. 10 according to one embodiment. FIG. 11B is a modified example of FIG. 11A according to one embodiment.

Referring to FIGS. 10 and 11A, a second display area CA may include a plurality of second pixel groups PG2 and a plurality of light-transmitting areas TA. Each of the second pixel groups PG2 may include a second-first pixel group PG21 and a second-second pixel group PG22 having different arrangements of sub-pixels. Each of the second pixel groups PG2 may include a first sub-pixel SP1, a second sub-pixel SP2, a third sub-pixel SP3, and a fourth sub-pixel SP4.

The first sub-pixel SP1 may include a first light-emitting element R, the second sub-pixel SP2 may include a second light-emitting element G1, the third sub-pixel SP3 may include a third light-emitting element B, and the fourth sub-pixel SP4 may include a fourth light-emitting element G2.

The first light-emitting element R may be a red light-emitting element, the second light-emitting element G1 and the fourth light-emitting element G2 may be green light-emitting elements, and the third light-emitting element B may be a blue light-emitting element, but the present disclosure is not necessarily limited thereto, and an emission wavelength of each light-emitting element may be variously modified.

The fourth sub-pixel SP4 may be disposed in a pixel row different from those of the first to third sub-pixels SP1 to SP3. As an example, in the second-first pixel group PG21, the first to third sub-pixels SP1 to SP3 may be disposed in a first pixel row RW1, while the fourth sub-pixel SP4 may be disposed in a second pixel row RW2. The second light-emitting element G1 of the second sub-pixel SP2 and the fourth light-emitting element G2 of the fourth sub-pixel SP4 may be disposed in the second diagonal direction D2.

However, the present disclosure is not necessarily limited thereto, and a circuit part of the fourth sub-pixel SP4 may be formed in the first pixel row RW1 and a portion of the fourth light-emitting element G2 may be disposed in the second pixel row RW2. That is, the meaning of the phrase “one sub-pixel is disposed in a pixel row different from those of the other sub-pixels” may include a case in which both a circuit part and a light-emitting element are disposed in different pixel rows, as well as a case in which at least a portion of the circuit part or the light-emitting element is disposed in different pixel rows.

In contrast, in the second-second pixel group PG22, the first sub-pixel SP1, the third sub-pixel SP3, and the fourth sub-pixel SP4 may be disposed in the second pixel row RW2, while the second sub-pixel SP2 may be disposed in the first pixel row RW1. That is, the adjacent second-first pixel group PG21 and second-second pixel group PG22 may have different pixel arrangements. According to such a configuration, the second sub-pixel SP2 of the second-second pixel group PG22 may be disposed in a light-transmitting area TA between the adjacent second-first pixel groups PG21 in the first direction, thereby improving uniformity and luminance.

The first light-emitting elements R and the third light-emitting elements B may be alternately disposed in the first direction. The second light-emitting element G1 may not overlap the first light-emitting element R and the third light-emitting element B in the first direction. In addition, the first light-emitting element R, the second light-emitting element G1, and the third light-emitting element B may be disposed so as not to overlap each other in the second direction.

The second light-emitting elements G1 or the fourth light-emitting elements G2 and the third light-emitting elements B may be alternately disposed in the first diagonal direction D1, and the first light-emitting element R may not overlap the second light-emitting element G1, the fourth light-emitting element G2, and the third light-emitting element B in the first diagonal direction D1.

The first light-emitting elements R and the second and fourth light-emitting elements G1 and G2 may be alternately disposed in the second diagonal direction D2, and the third light-emitting element B may not overlap the first light-emitting element R, the second and fourth light-emitting elements G1 and G2 in the second diagonal direction D2.

According to this arrangement, since the second sub-pixel SP2 and the fourth sub-pixel SP4 may uniformly disposed in the diagonal direction, there is an advantage in that uniform image quality may be realized even when some pixels are omitted in comparison with the first display area DA. In addition, a pixel pattern may not be observed from the outside, so that image quality may be improved.

Although the case in which a plurality of light-transmitting areas TA of various sizes may be formed has been exemplified, a size of each of the light-transmitting areas TA may be the same. As an example, each of the light-transmitting areas TA may have the size corresponding to a size of the sub-pixel.

Referring to FIG. 11B, the light-transmitting area TA may be disposed between the third sub-pixel SP3 and the fourth sub-pixel SP4 constituting the second pixel group PG2. In the case in which the light-transmitting area TA between the second pixel groups PG2 is large, there is a problem in that luminance of the corresponding light-transmitting area TA is relatively reduced such that image quality is degraded, but according to the embodiment, the fourth sub-pixel SP4 may be disposed between the light-transmitting areas TA so that uniformity and luminance may be improved.

As an example, the light-transmitting area TA may be disposed between the third sub-pixel SP3 and the fourth sub-pixel SP4 in the second-first pixel group PG21, while the light-transmitting area TA may be disposed between the second sub-pixel SP2 and the third sub-pixel SP3 in the second-second pixel group PG22. In addition, a size of the light-transmitting area TA disposed in the second-first pixel group PG21 and a size of the light-transmitting area TA disposed in the second-second pixel group PG22 may be different.

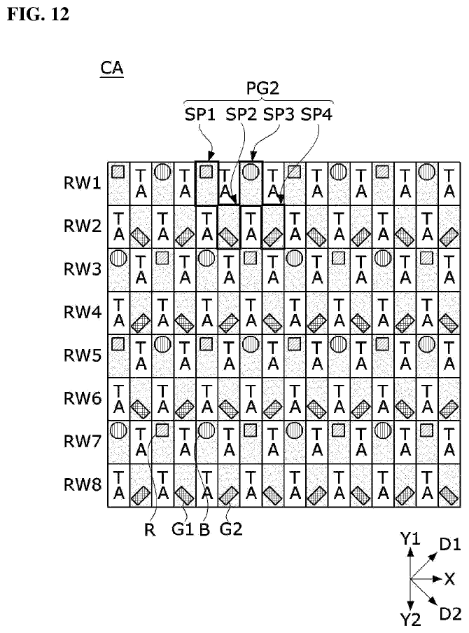

According to an embodiment, a method of grouping a plurality of sub-pixels to form a pixel group may be variously modified. FIG. 12 is a view illustrating a pixel arrangement in a second display area according to a third embodiment of the present disclosure.

Referring to FIG. 12, a first sub-pixel SP1 and a third sub-pixel SP3 may be disposed in a first pixel row RW1, while a second sub-pixel SP2 and a fourth sub-pixel SP4 may be disposed in a second pixel row RW2.

Accordingly, first light-emitting elements R and third light-emitting elements B may be alternately disposed in the first pixel row RW1, and second light-emitting elements G1 and fourth light-emitting elements G2 may be alternately disposed in the second pixel row RW2.

However, the present disclosure is not necessarily limited thereto, and a circuit part of each of the second sub-pixel SP2 and the fourth sub-pixel SP4 may be formed in the first pixel row RW1, and a portion of each of the second light-emitting element G1 and the fourth light-emitting element G2 may be disposed in the second pixel row RW2.

In addition, the second light-emitting element G1 of the second sub-pixel SP2 and the fourth light-emitting element G2 of the fourth sub-pixel SP4 may have different shapes. As an example, the second light-emitting element G1 may have a shape extending in the second diagonal direction D2, while the fourth light-emitting element G2 may have a shape extending in the first diagonal direction D1.

The second light-emitting element G1 in the second pixel row RW2 and the second light-emitting element G1 in a fourth pixel row RW4 may also be manufactured to have different shapes. That is, the second light-emitting elements G1 may be manufactured to have different shapes in the second direction. Similarly, the fourth light-emitting element G2 of the second pixel row RW2 and the fourth light-emitting element G2 of the fourth pixel row RW4 may be manufactured to have different shapes in the second direction.

Since the light-emitting elements may be variously modified in this way, when an organic light-emitting element is formed on a substrate, a fine metal mask (FMM) for the first display area and an FMM for the second display area CA may be differently manufactured.

As an example, in the FMM for the first display area, openings having the same shape may be formed in the second light-emitting element G1 and the fourth light-emitting element G2, while in the FMM for the second display area, openings may be formed by changing the shape and arrangement of the light-emitting elements to be advantageous in improving image quality. Thus, the shape and/or arrangement of the pixels in the first display area DA and the shape and/or arrangement of the pixels in the second display area CA may be different.

According to the embodiment, uniformity and luminance may be improved by differently forming the shape and/or arrangement of the light-emitting elements of the first display area DA and the light-emitting elements of the second display area CA. According to an embodiment, a method of grouping a plurality of sub-pixels to form a pixel group may be variously modified.

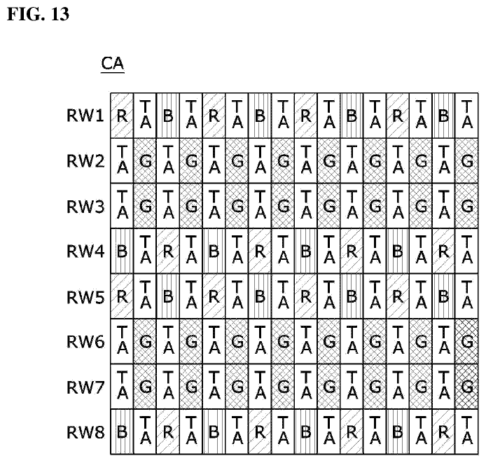

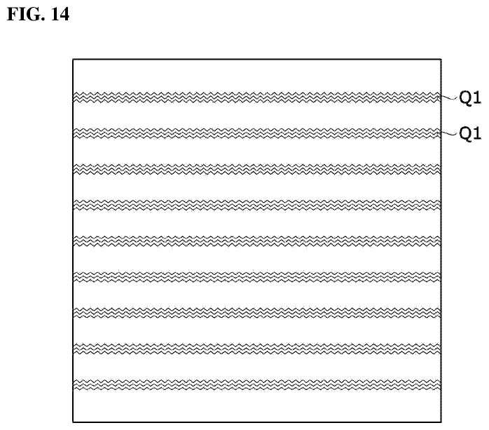

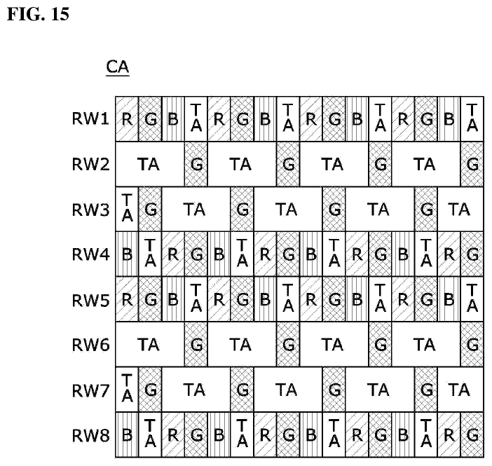

FIG. 13 is a first comparative example illustrating a pixel arrangement in a second display area according to one embodiment. FIG. 14 illustrates a result of observing whether patterns are recognized from the outside according to one embodiment. FIG. 15 is a second comparative example illustrating a pixel arrangement in a second display area according to one embodiment.

Referring to FIG. 13, a red light-emitting element and a blue light-emitting element may be disposed in each of a first pixel row RW1 and a fourth pixel row RW4, and green light-emitting elements may be disposed in a second pixel row RW2. In this case, the green light-emitting elements may also be disposed in a third pixel row RW3.

Accordingly, since only the green light-emitting elements are disposed in the second pixel row RW2 and the third pixel row RW3, there is a problem that luminance uniformity is relatively lowered. As a result, as shown in FIG. 14, a line-shaped pattern Q1 is observed from the outside, and thus there is a problem that image quality is degraded.

Referring to FIG. 15, only a green light-emitting element is disposed in a second pixel row RW2 and a third pixel row RW3, and thus there is a problem that a line-shaped pattern is recognized from the outside. In contrast, in the case of the embodiments of the present disclosure, since the sub-pixels are relatively uniformly disposed, there is an effect of improving image quality.

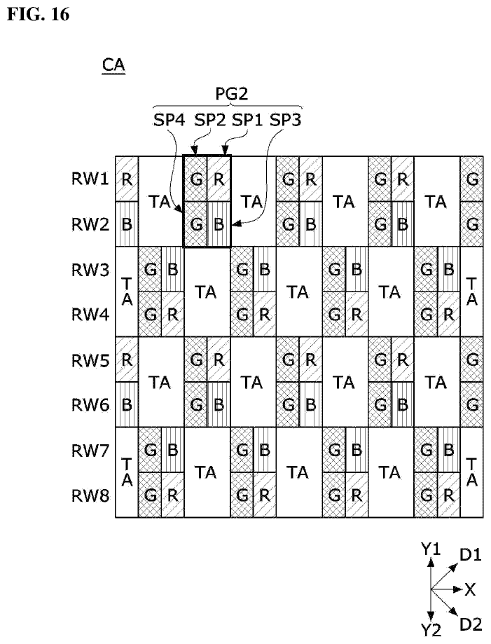

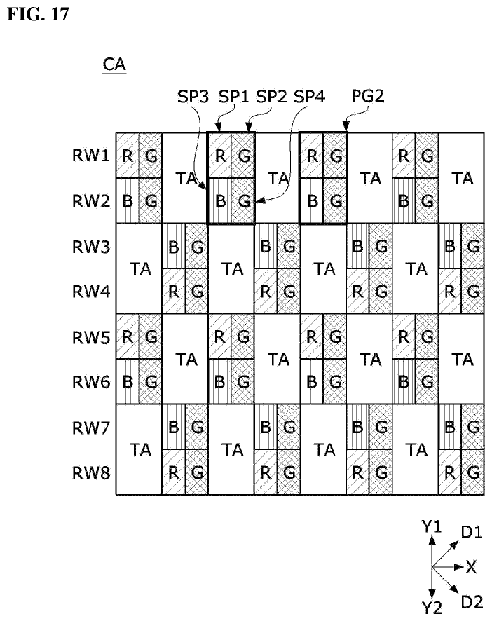

FIG. 16 is a view illustrating a pixel arrangement in a second display area according to a fourth embodiment of the present disclosure. FIG. 17 is a view illustrating a pixel arrangement in a second display area according to a fifth embodiment of the present disclosure.

Referring to FIG. 16, in a second pixel group PG2, a first sub-pixel SP1 and a second sub-pixel SP2 may be disposed in a first pixel row RW1 and a third sub-pixel SP3 and a fourth sub-pixel SP4 may be disposed in a second pixel row RW2.

In addition, the second sub-pixel SP2 and the third sub-pixel SP3 may be disposed in the second diagonal direction D2, and the first sub-pixel SP1 and the third sub-pixel SP3 may be disposed in the first diagonal direction D1. Light-transmitting areas TA may be disposed between a plurality of second pixel groups PG2. The light-transmitting area TA may also be formed to correspond to a size of the second pixel group PG2.

Referring to FIG. 17, in a second pixel group PG2, a first sub-pixel SP1 and a second sub-pixel SP2 may be disposed in a first pixel row RW1 and a third sub-pixel SP3 and a fourth sub-pixel SP4 may be disposed in a second pixel row RW2.

In addition, the first sub-pixel SP1 and the fourth sub-pixel SP4 may be disposed in the second diagonal direction D2, and the second sub-pixel SP2 and the third sub-pixel SP3 may be disposed in the first diagonal direction D1. Light-transmitting areas TA may be disposed between a plurality of second pixel groups PG2. The light-transmitting area TA may also be formed to correspond to a size of the second pixel group PG2.

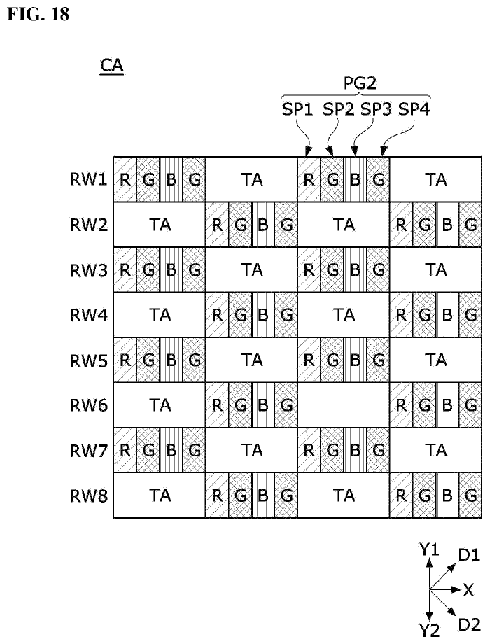

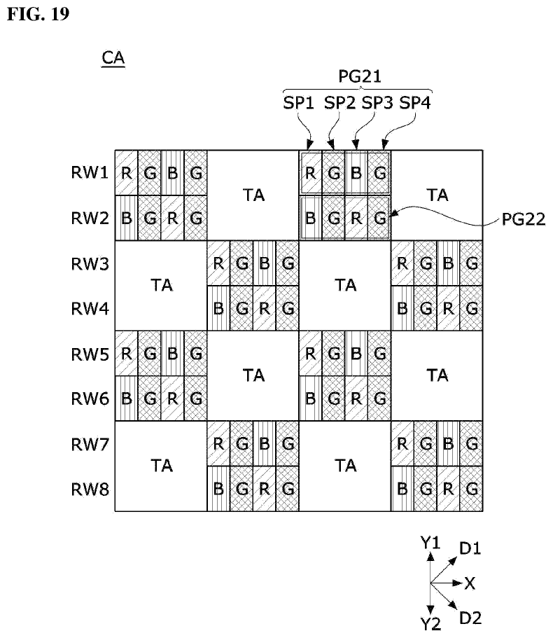

FIG. 18 is a view illustrating a pixel arrangement in a second display area according to a sixth embodiment of the present disclosure. FIG. 19 is a view illustrating a pixel arrangement in a second display area according to a seventh embodiment of the present disclosure.

Referring to FIG. 18, in a second pixel group PG2, first to fourth sub-pixels SP1, SP2, SP3, and SP4 may be disposed in the same pixel row. The second pixel groups PG2 and light-transmitting areas TA may be alternately disposed in the first direction and the second direction. Here, a size of the light-transmitting area TA may correspond to a size of the second pixel group PG2.

Referring to FIG. 19, a second pixel group PG2 includes first to fourth sub-pixels SP1, SP2, SP3, and SP4, and the second pixel groups PG2 and light-transmitting areas TA may be alternately disposed in the first direction. In the second direction, second-first pixel groups PG21 and second-second pixel groups PG22 may be alternately disposed. In the second-first pixel group PG21 and the second-second pixel group PG22, positions of the first and third sub-pixels SP1 and SP3 may be different from each other.

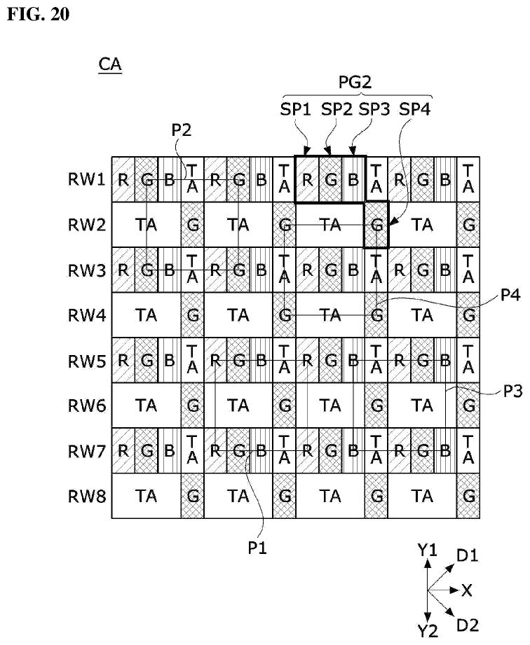

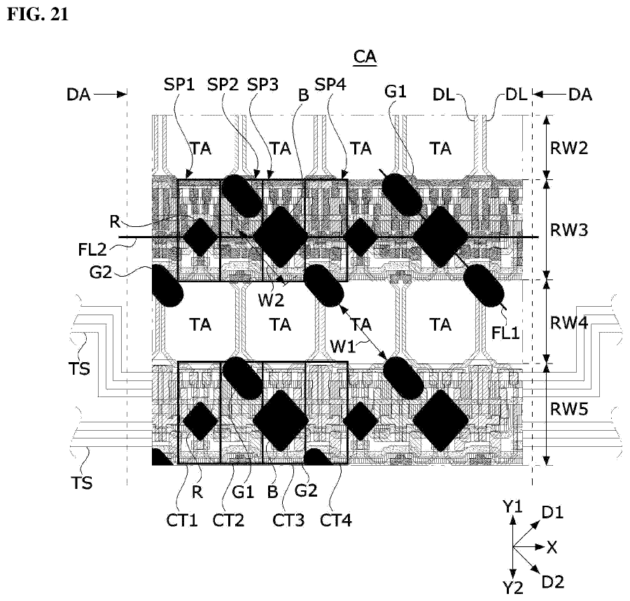

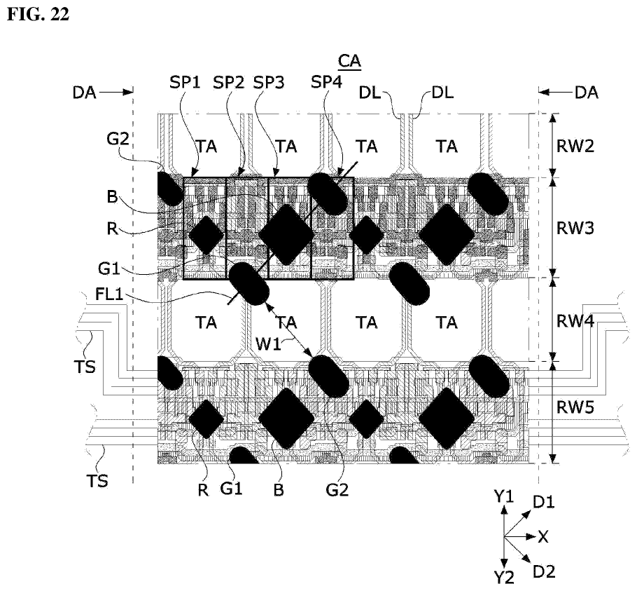

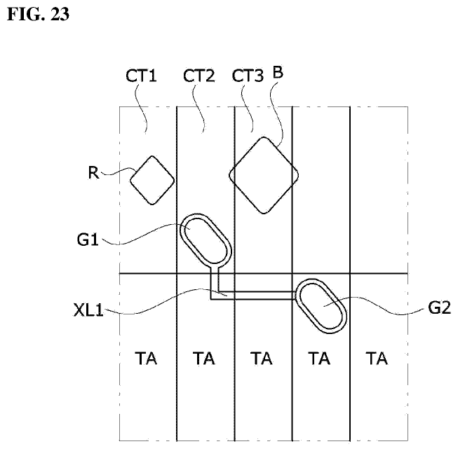

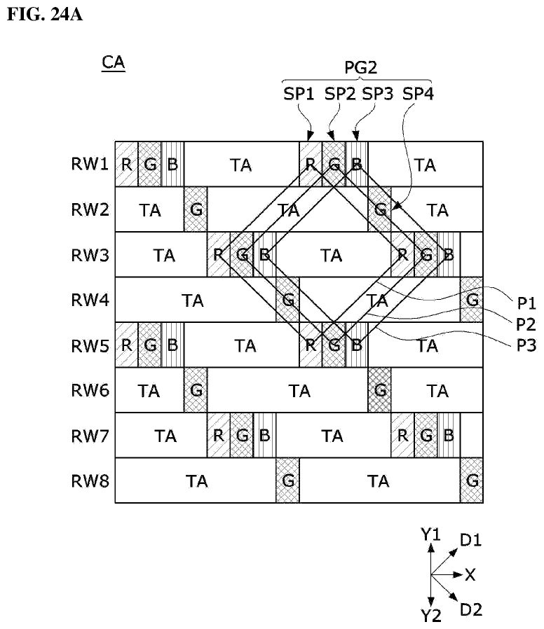

FIG. 20 is a view illustrating a pixel arrangement of a second display area according to an eighth embodiment of the present disclosure, FIG. 21 is an enlarged view of FIG. 20, FIG. 22 is a modified example of FIG. 21, and FIG. 23 is a second modified example of FIG. 21.

Referring to FIG. 20, in a second pixel group PG2, a first sub-pixel SP1, a second sub-pixel SP2, and a third sub-pixel SP3 may be disposed in the first direction, and a fourth sub-pixel SP4 may be disposed in the second diagonal direction D2 of the third sub-pixel SP3.

Light-transmitting areas TA may be disposed between a plurality of second pixel groups PG2. In this case, the light-transmitting area TA may include an area corresponding to a width of each sub-pixel and an area corresponding to a width of the three sub-pixels. That is, sizes of the plurality of light-transmitting areas TA may be different from each other. However, the present disclosure is not necessarily limited thereto, and the sizes of the plurality of light-transmitting areas TA may also be the same.

The first to third sub-pixels SP1 to SP3 may be alternately disposed in the first direction. The fourth sub-pixel SP4 may not overlap the first to third sub-pixels SP1 to SP3 in the first direction. The first to fourth sub-pixels SP1, SP2, SP3, and SP4 may be disposed so as not to overlap each other in the second direction.

The first to fourth sub-pixels SP1, SP2, SP3, and SP4 of the plurality of second pixel groups PG2 may be disposed on each of square-shaped lines P1, P2, P3, and P4. In addition, the first to third sub-pixels SP1 to SP3 may be disposed inside the square-shaped line P4 connecting the fourth sub-pixels SP4. According to this arrangement, since all the sub-pixels are uniformly disposed, even when some pixels are omitted in comparison with the first display area DA, uniform image quality may be realized. In addition, a pixel pattern may not be observed from the outside, so that image quality may be improved.

In the embodiment, it is described that the fourth sub-pixel SP4 is disposed in a pixel row different from those of the first to third sub-pixels SP1 to SP3, but the present disclosure is not necessarily limited thereto. A circuit part of the fourth sub-pixel SP4 may be formed in a first pixel row RW1 and a portion of a fourth light-emitting element may be disposed in a second pixel row RW2.

Referring to FIG. 21, a second display area CA may include odd-numbered pixel rows RW3 and RW5 in which a plurality of second pixel groups PG2 are continuously disposed in the first direction, and even-numbered pixel rows RW2 and RW4 in which a plurality of light-transmitting areas TA are continuously disposed in the first direction, and the odd-numbered pixel rows RW3 and RW5 and the even-numbered pixel rows RW2 and RW4 may be alternately disposed in the second direction.

Circuit parts CT1, CT2, CT3, and CT4 of the sub-pixels SP1, SP2, SP3, and SP4 disposed in each of the odd-numbered pixel rows RW3 and RW5 may be continuously disposed in the first direction. Thus, there is an advantage in that a line design is simplified because the light-transmitting area TA is not disposed between the sub-pixels. When the plurality of light-transmitting areas are disposed between the sub-pixels, the line design may be complicated because the line has to bypass the light-transmitting area.

The circuit part CT4 of the fourth sub-pixel SP4 may be continuously disposed in the first direction together with the circuit parts CT1, CT2, and CT3 of the first to third light-emitting elements. That is, the circuit part of each sub-pixel may be continuously formed in the third pixel row RW3. Thus, the light-transmitting area TA disposed in the fourth pixel row RW4 may be continuously disposed.

The light-transmitting area TA disposed in the third pixel row RW3 may be divided into a plurality of areas by data lines DL. However, the present disclosure is not necessarily limited thereto, and a size of the light-transmitting area TA may vary depending on a change in the design of the data line.

A first imaginary line FL1, which connects a center of each of a second light-emitting element G1 and a fourth light-emitting element G2 in the second pixel group PG2, may intersect the first direction and the second direction. That is, the second light-emitting element G1 and the fourth light-emitting element G2 may be disposed in the second diagonal direction D2 with a third light-emitting element B interposed therebetween.

The second light-emitting element G1 may be disposed on one side (an upper side) of a second imaginary line FL2 passing through a center of each of a first light-emitting element R and the third light-emitting element B, and the fourth light-emitting element G2 may be disposed on the other side (a lower side) of the second imaginary line FL2. However, the present disclosure is not necessarily limited thereto, the second light-emitting element G1 may be disposed on the lower side of the second imaginary line FL2 and the fourth light-emitting element G2 may be disposed on the upper side of the second imaginary line FL2.

According to the embodiment, the first imaginary line FL1 may intersect the second imaginary line FL2. Accordingly, a portion of the fourth light-emitting element G2 may be disposed to overlap the light-transmitting area TA. Here, an anode disposed below the fourth light-emitting element G2 may also extend onto the light-transmitting area TA. According to this configuration, luminance and uniformity may be improved by partially disposing the fourth light-emitting element G2 in the light-transmitting area TA.

It is illustrated that a portion of the fourth light-emitting element G2 is disposed outside the light-transmitting area TA, but the present disclosure is not necessarily limited thereto. As an example, the fourth light-emitting element G2 may be disposed at the center of the light-transmitting area TA. In this case, the anode may extend to connect the circuit part CT4 and the fourth light-emitting element G2. The anode may be formed as a transparent electrode, but the present disclosure is not necessarily limited thereto.

According to the embodiment, since the fourth light-emitting element G2 is disposed in the light-transmitting area TA, a first distance W1 between the fourth light-emitting element G2 disposed in the third pixel row RW3 and the second light-emitting element G1 disposed in the fifth pixel row RW5 may be relatively small. The first distance W1 may be substantially similar to a second distance W2 between the second light-emitting element G1 and the fourth light-emitting element G2 in the same second pixel group PG2.

Thus, the distance between the second light-emitting element G1 and the fourth light-emitting element G2 may be regularly arranged in the second display area CA even when the plurality of light-transmitting areas TA are continuously disposed in the third pixel row RW3, so that luminance may be uniform. In addition, image quality may be improved.

Lines TS connected to each sub-pixel may be configured to avoid the light-transmitting area TA. As an example, the lines TS, such as a data line, a scan line, and an EM line, connected to each sub-pixel may be designed to bypass the light-transmitting area TA as much as possible. As an example, the lines TS extending from the fourth pixel row RW4 of the first display area DA may be designed to bypass the fifth pixel row RW5 in the second display area CA.

A portion of a cathode corresponding to the light-transmitting area TA may be patterned to increase light transmittance. Also, as described above, a first light-transmitting pattern corresponding to the light-transmitting area may also be formed on the polarizing plate to increase light transmittance.

Referring to FIG. 22, the second light-emitting element G1 rather than the fourth light-emitting element G2 may be disposed in the light-transmitting area TA. Alternatively, the second light-emitting element G1 may be disposed adjacent to the light-transmitting area TA disposed on a lower side thereof, and the fourth light-emitting element G2 may be disposed adjacent to the light-transmitting area TA disposed on an upper side thereof. In this case, the light-emitting element may be disposed in the light-transmitting area TA to improve image quality.

Referring to FIG. 23, the fourth light-emitting element G2 may function as a dummy pixel that emits light by being connected to a circuit part CT1 of the second light-emitting element G1 without being individually controlled by the circuit part. In this case, a connection line XL1 connecting between the fourth light-emitting element G2 and the second light-emitting element G1 may be further formed. The connection line XL1 may be manufactured as a transparent electrode, such as ITO, but the present disclosure is not necessarily limited thereto.

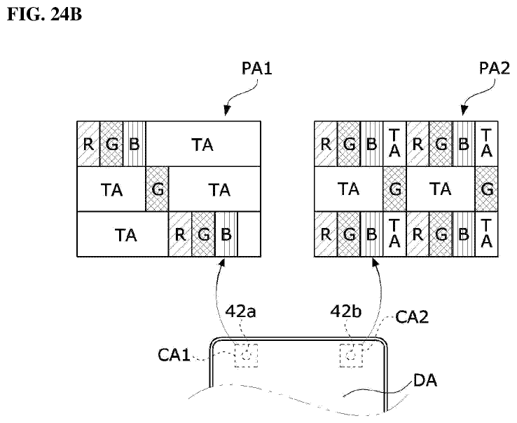

FIG. 24A is a view illustrating a pixel arrangement in a second display area according to a ninth embodiment of the present disclosure.

Referring to FIG. 24A, a plurality of second pixel groups PG2 may be disposed to be spaced apart from each other in the first direction. In comparison with the second pixel groups PG2 of FIG. 20 being continuously disposed in the first direction, in FIG. 24A, a light-transmitting area TA is also disposed between the plurality of second pixel groups PG2, and thus the number of pixels may be reduced by ½ as compared with the second display area of FIG. 20. Accordingly, light may be sufficiently incident on the light-transmitting areas TA that are increased.

Each of the sub-pixels disposed in the plurality of second pixel groups PG2 may be disposed in a quadrangular shape inclined at 45°. As an example, a plurality of first sub-pixels SP1 may be disposed on a first quadrangular-shaped line P1, a plurality of second sub-pixels SP2 may be disposed on a second quadrangular-shaped line P2, and a plurality of third sub-pixels SP3 may be disposed on a third quadrangular-shaped line P3.

FIG. 24B is a view illustrating a structure in which an area of a light-transmitting area varies in a second display area according to one embodiment.

Referring to FIG. 24B, a second display area CA may include a first unit area CA2 having a smaller number of pixels than the first display area DA and a second unit area CA1 having a smaller number of pixels than the first unit area CA2. That is, resolution may be different even in the second display area CA.

A plurality of electronic devices may be disposed below the second display area CA. As an example, the plurality of electronic devices may include an ambient light sensor that determines surrounding brightness, a proximity sensor, a camera module having an image sensor embedded therein, and an infrared sensor that receives infrared light. A camera module 42a includes an infrared filter to cut off light of an infrared wavelength band and receive visible light, while an infrared sensor 42b may receive the light of an infrared wavelength band.

Here, the infrared sensor 42b may enable relatively accurate measurement even when the amount of light is small in comparison with the camera module 42a. Thus, the number of pixels of the second unit area CA1 in which the camera module 42a is disposed may be less than the number of pixels of the first unit area CA2 in which the infrared sensor 42b is disposed.

As an example, a pixel pattern PA1 of the second unit area CA1 may have the pixel pattern shown in FIG. 24A, and a pixel pattern PA2 of the first unit area CA2 may have the pixel pattern shown in FIG. 20. As an example, the first unit area CA2 may be designed to have a light transmittance of 10% to 30%. Thus, the amount of incident light may be relatively greater in the second unit area CAL However, such pixel patterns are not necessarily limited thereto, and the pixel patterns described in the present specification may be applied without limitation.

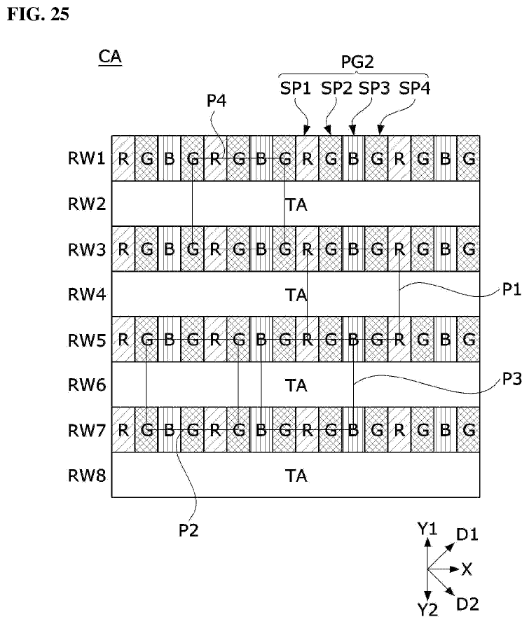

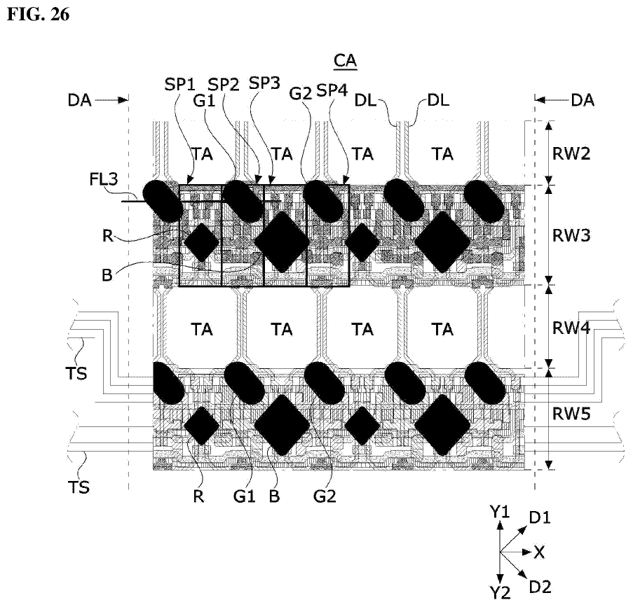

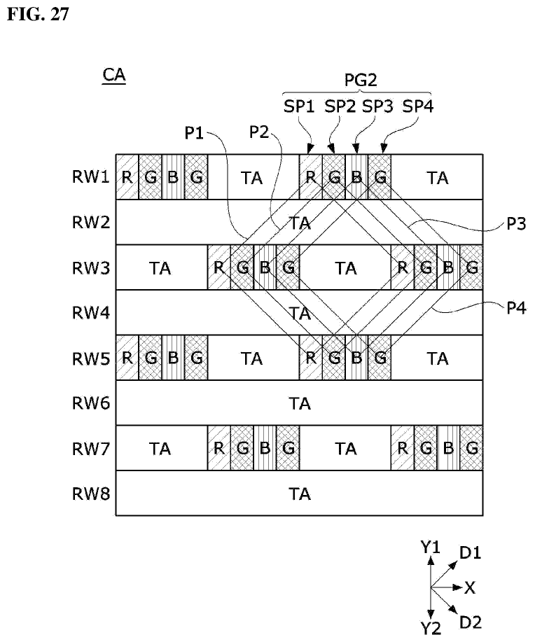

FIG. 25 is a view illustrating a pixel arrangement of a second display area according to a tenth embodiment of the present disclosure, FIG. 26 is an enlarged view of FIG. 25 according to the tenth embodiment, and FIG. 27 is a view illustrating a pixel arrangement of a second display area according to an eleventh embodiment of the present disclosure.

Referring to FIG. 25, a plurality of second pixel groups PG2 may be disposed in a first pixel row RW1, and a plurality of light-transmitting areas TA may be disposed in a second pixel row RW2. In this case, the number of pixels is reduced by ½ in comparison with the first display area DA so that a sufficient amount of light may be injected into a sensor.

First to fourth sub-pixels SP1, SP2, SP3, and SP4 of the plurality of second pixel groups PG2 may be disposed on each of square-shaped lines P1, P2, P3, and P4. According to this arrangement, since all the sub-pixels are uniformly disposed, even when some pixels are omitted in comparison with the first display area DA, uniform image quality may be realized. In addition, a pixel pattern may not be observed from the outside, so that uniform image quality may be implemented.

Referring to FIG. 26, a third imaginary line FL3 connecting a second light-emitting element G1 and a fourth light-emitting element G2 may be parallel to the first direction. This pixel arrangement may be the same as the pixel arrangement of the first display area.

Lines TS connected to each sub-pixel may be configured to avoid the light-transmitting area TA. As an example, a data line, a scan line, and an EM line that are connected to each sub-pixel may be designed to bypass the light-transmitting area TA as much as possible. In addition, a portion of a cathode corresponding to the light-transmitting area TA may be patterned to increase light transmittance.

Referring to FIG. 27, a plurality of second pixel groups PG2 may be disposed to be spaced apart from each other in the first direction. In comparison with the second pixel groups PG2 of FIG. 25 being continuously disposed in the first direction, a light-transmitting area TA is disposed between the plurality of second pixel groups PG2 of FIG. 27, and thus the number of pixels may be further reduced. Accordingly, light may be sufficiently incident on the light-transmitting areas TA that are increased.

Each of sub-pixels SP1, SP2, SP3, and SP4 disposed in the plurality of second pixel groups PG2 may be disposed on square-shaped lines inclined at 45°. As an example, a plurality of first sub-pixels SP1 may be disposed on a first square-shaped line P1, a plurality of second sub-pixels SP2 may be disposed on a second square-shaped line P2, a plurality of third sub-pixels SP3 may be disposed on a third square-shaped line P3, and a plurality of fourth sub-pixels SP4 may be disposed on a fourth square-shaped line P4.

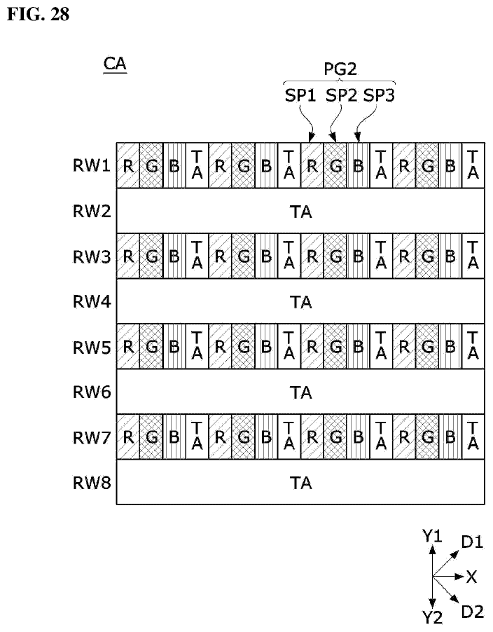

FIG. 28 is a view illustrating a pixel arrangement in a second display area according to a twelfth embodiment of the present disclosure.

FIG. 28 illustrates a structure in which the fourth sub-pixel SP4 is omitted from the second pixel group PG2 of FIG. 20. Accordingly, first to third sub-pixels SP1 to SP3 may be implemented as a real-type pixel constituting one pixel, but the present disclosure is not necessarily limited thereto.

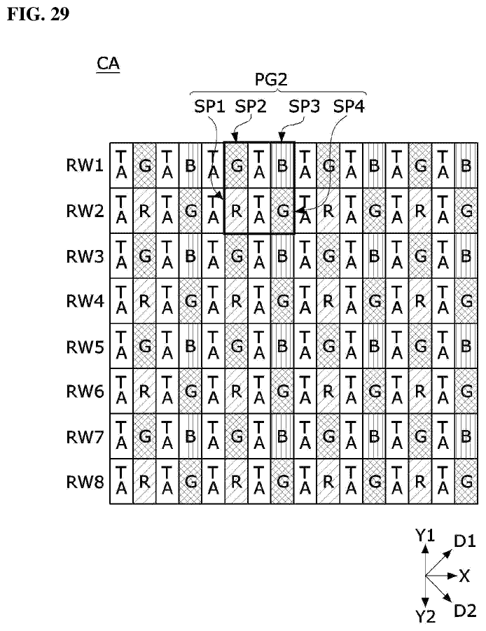

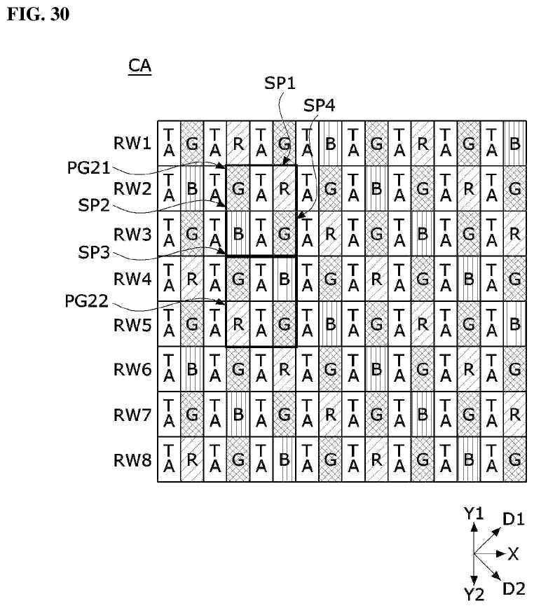

FIG. 29 is a view illustrating a pixel arrangement in a second display area according to a thirteenth embodiment of the present disclosure, and FIG. 30 is a view illustrating a pixel arrangement in a second display area according to a fourteenth embodiment of the present disclosure.

Referring to FIG. 29, a plurality of sub-pixels constituting a second pixel group PG2 may be disposed in two pixel rows RW1 and RW2. As an example, a second sub-pixel SP2 and a third sub-pixel SP3 may be disposed in a first pixel row RW1, and a first sub-pixel SP1 and a fourth sub-pixel SP4 may be disposed in a second pixel row RW2.

A light-transmitting area TA may be disposed between the second sub-pixel SP2 and the third sub-pixel SP3 in the first pixel row RW1 and may be disposed between the first sub-pixel SP1 and the fourth sub-pixel SP4 in the second pixel row RW2.

A plurality of second pixel groups PG2 may be disposed to be spaced apart from each other in the first direction but may be continuously disposed in the second direction. However, the present disclosure is not necessarily limited thereto, and the plurality of second pixel groups PG2 may also be disposed to be spaced apart from each other in the second direction.

Referring to FIG. 30, a plurality of second pixel groups PG2 may include a second-first pixel group PG21 and a second-second pixel group PG22 having different pixel arrangements.

As an example, in the second-first pixel group PG21, a first sub-pixel SP1 and a second sub-pixel SP2 may be disposed in a second pixel row RW2, and a third sub-pixel SP3 and a fourth sub-pixel SP4 may be disposed in a third pixel row RW3.

However, in the second-second pixel group PG22, the second sub-pixel SP2 and the third sub-pixel SP3 may be disposed in a fourth pixel row RW4, and the first sub-pixel SP1 and the fourth sub-pixel SP4 may be disposed in a fifth pixel row RW5.

That is, between the adjacent second pixel groups PG2, positions of green sub-pixels may be the same, but the arrangement of red sub-pixels and blue sub-pixels may be different. In this case, the sub-pixels of the same color may be disposed in the second diagonal direction D2. That is, a plurality of first sub-pixels SP1 may be disposed in the second diagonal direction D2, a plurality of second sub-pixels SP2 may be disposed in the second diagonal direction D2, a plurality of third sub-pixels SP3 may be disposed in the second diagonal direction D2, and a plurality of fourth sub-pixels SP4 may be disposed in the second diagonal direction D2.

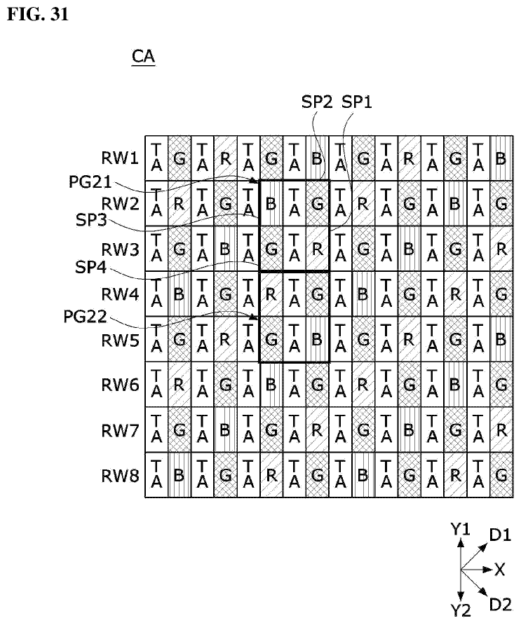

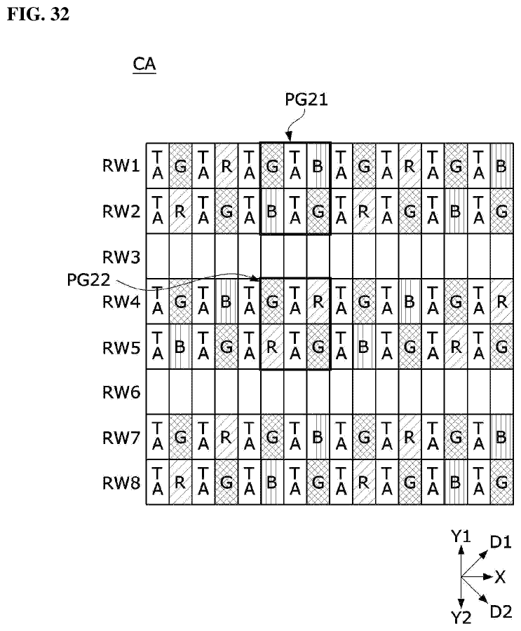

FIG. 31 is a view illustrating a pixel arrangement in a second display area according to a fifteenth embodiment of the present disclosure, and FIG. 32 is a view illustrating a pixel arrangement in a second display area according to a sixteenth embodiment of the present disclosure.

Referring to FIG. 31, positions of red sub-pixels and blue sub-pixels may be disposed opposite to those in FIG. 30. Thus, a plurality of first sub-pixels SP1 may be disposed in the first diagonal direction D1, a plurality of second sub-pixels SP2 may be disposed in the first diagonal direction D1, a plurality of third sub-pixels SP3 may be disposed in the first diagonal direction D1, and a plurality of fourth sub-pixels SP4 may be disposed in the first diagonal direction D1. In addition, as shown in FIG. 32, a plurality of second pixel groups PG2 may also be spaced apart from each other in the second direction.

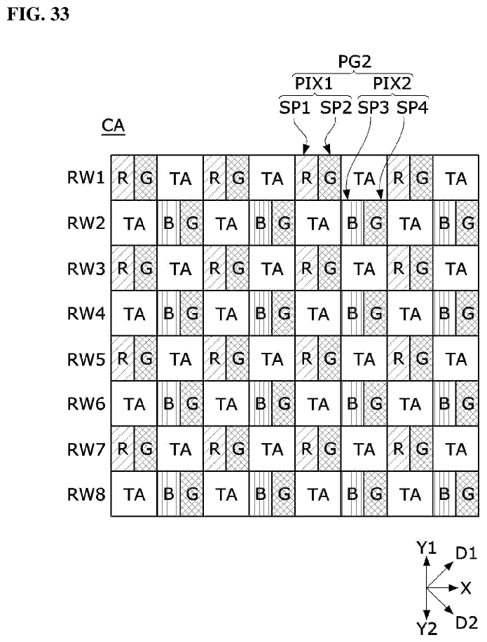

FIG. 33 is a view illustrating a pixel arrangement in a second display area CA according to a seventeenth embodiment of the present disclosure.

Referring to FIG. 33, a plurality of sub-pixels constituting a second pixel group PG2 may be disposed in two pixel rows. As an example, a first sub-pixel SP1 and a second sub-pixel SP2 may be disposed in a first pixel row RW1, and a third sub-pixel SP3 and a fourth sub-pixel SP4 may be disposed in a second pixel row RW2.

The first sub-pixel SP1 and the second sub-pixel SP2 may constitute a first unit pixel PIX1, and the third sub-pixel SP3 and the fourth sub-pixel SP4 may constitute a second unit pixel PIX2. Here, the first unit pixel PIX1 and the second unit pixel PIX2 may be disposed to be shifted from each other so as not to overlap in the second direction.

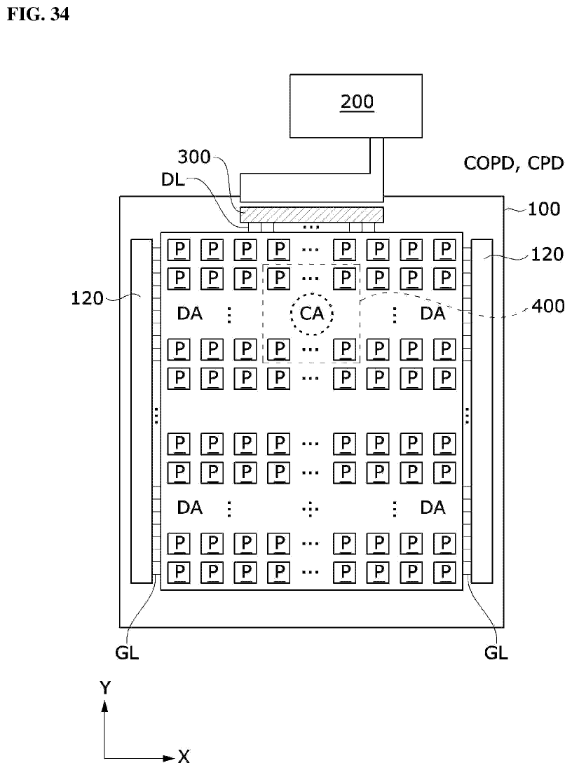

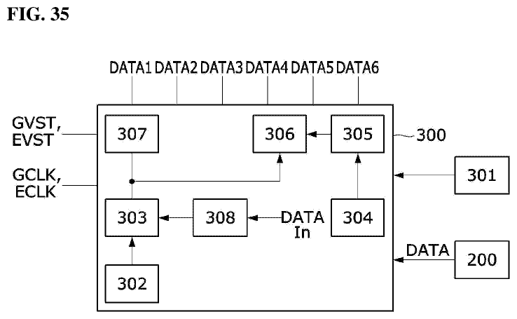

FIG. 34 is a block diagram illustrating a display panel and a display panel driving unit according to an embodiment of the present disclosure, and FIG. 35 is a schematic block diagram illustrating a configuration of a driver integrated circuit (IC) according to one embodiment.

Referring to FIGS. 34 and 35, the display device may include a display panel 100 having a pixel array disposed on a screen, a display panel driving unit, and the like.

The pixel array of the display panel 100 may include data lines DL, gate lines GL intersecting the data lines DL, and pixels P arranged in a matrix form defined by the data lines DL and the gate lines GL.

In the display panel 100, the screen on which an input image is reproduced may include a first display area DA and a second display area CA.

Sub-pixels of each of the first display area DA and the second display area CA may include a pixel circuit. The pixel circuit may include a driving element configured to supply current to a light-emitting element OLED, a plurality of switch elements configured to sample a threshold voltage of the driving element and switch current paths of the pixel circuit, a capacitor configured to maintain a gate voltage of the driving element, and the like. The pixel circuit may be disposed below the light-emitting element.

The second display area CA may include light-transmitting areas TA disposed between pixel groups and a camera module 400 disposed below the second display area CA. In an imaging mode, the camera module 400 may perform photoelectric conversion on light incident through the second display area CA using an image sensor and convert pixel data of an image, which is output from the image sensor, into digital data to output imaged image data.

The display panel driving unit may write the pixel data of the input image to the pixels P. The pixels P may be interpreted as a pixel group including a plurality of sub-pixels.

The display panel driving unit may include a data driving unit 306 configured to supply a data voltage of the pixel data to the data lines DL, and a gate driving unit 120 configured to sequentially supply a gate pulse to the gate lines GL. The data driving unit 306 may be integrated into a driver IC 300. The display panel driving unit may further include a touch sensor driving unit omitted from the drawing.

The driver IC 300 may be attached to the display panel 100. The driver IC 300 receives pixel data of an input image and a timing signal from a host system 200, supplies a data voltage of the pixel data to the pixels, and synchronizes the data driving unit 306 with the gate driving unit 120.

The driver IC 300 may be connected to the data lines DL through data output channels to supply the data voltage of the pixel data to the data lines DL. The driver IC 300 may output a gate timing signal for controlling the gate driving unit 120 through gate timing signal output channels.

The gate timing signal generated from a timing controller 303 may include a gate start pulse VST, a gate shift clock CLK, and the like. The gate start pulse VST and the gate shift clock CLK may swing between a gate-on voltage VGL and a gate-off voltage VGH.

The gate timing signal (VST and CLK) output from a level shifter 307 may be applied to the gate driving unit 120 to control a shift operation of the gate driving unit 120.

The gate driving unit 120 may include a shift register formed on the circuit layer of the display panel 100 together with the pixel array. The shift register of the gate driving unit 120 may sequentially supply a gate signal to the gate lines GL under the control of the timing controller. The gate signal may include a scan pulse and an EM pulse of an emission signal.

The shift register may include a scan driving unit configured to output the scan pulse, and an EM driving unit configured to output the EM pulse. In FIG. 35, “GVST” and “GCLK” are signals included in the gate timing signal that is input to the scan driving unit. “EVST” and “ECLK” are signals included in the gate timing signal that is input to the EM driving unit.

The driver IC 300 may be connected to the host system 200, a first memory 301, and the display panel 100. The driver IC 300 may include a data reception and computation unit 308, the timing controller 303, the data driving unit 306, a gamma compensation voltage generation unit 305, a power supply unit 304, a second memory 302, and the like.

The data reception and computation unit 308 may include a reception unit configured to receive pixel data input as a digital signal from the host system 200 and a data computation unit configured to process the pixel data input through the reception unit to improve image quality.

The data computation unit may include a data restoration unit configured to perform restoration by decoding compressed pixel data, an optical compensation unit configured to add a preset optical compensation value to the pixel data, and the like. The optical compensation value may be set as a value for correcting luminance of each piece of pixel data based on the luminance of the screen that is measured on the basis of a camera image captured in a manufacturing process.

The timing controller 303 may provide the pixel data of the input image received from the host system 200 to the data driving unit 306. The timing controller 303 may generate a gate timing signal for controlling the gate driving unit 120 and a source timing signal for controlling the data driving unit 306 to control operation timing of the gate driving unit 120 and the data driving unit 306.

The data driving unit 306 may convert digital data including the pixel data received from the timing controller 303 into a gamma compensation voltage using a digital-to-analog converter (DAC) and output a data voltage. The data voltage output from the data driving unit 306 may be supplied to the data lines DL of the pixel array through an output buffer connected to a data channel of the driver IC 300.

The gamma compensation voltage generation unit 305 may generate a gamma compensation voltage for each grayscale by dividing a gamma reference voltage received from the power supply unit 304 through a voltage divider circuit. The gamma compensation voltage is an analog voltage in which a voltage is set for each grayscale of the pixel data. The gamma compensation voltage output from the gamma compensation voltage generation unit 305 may be provided to the data driving unit 306.

The power supply unit 304 may generate power necessary to drive the driver IC 300, the gate driving unit 120, and the pixel array of the display panel 100 using a DC-DC converter. The DC-DC converter may include a charge pump, a regulator, a buck converter, a boost converter, and the like.

The power supply unit 304 may generate DC voltages such as a gamma reference voltage, a gate-on voltage VGL, a gate-off voltage VGH, a pixel driving voltage VDD, a low-potential power supply voltage VSS, an initialization voltage Vini, and the like by adjusting a DC input voltage received from the host system 200.

The gamma reference voltage may be supplied to the gamma compensation voltage generation unit 305. The gate-on voltage VGL and the gate-off voltage VGH may be supplied to the level shifter 307 and the gate driving unit 120. Pixel power voltages such as the pixel driving voltage VDD, the low-potential power supply voltage VSS, and the initialization voltages Vini may be supplied in common to the pixels P.

The initialization voltage Vini may be set to a DC voltage that is lower than the pixel driving voltage VDD and is lower than a threshold voltage of the light-emitting element OLED to initialize main nodes of the pixel circuits and suppress light emission of the light-emitting element OLED.

When power is supplied to the driver IC 300, the second memory 302 may store a compensation value, register setting data, and the like that are received from the first memory 301.

The compensation value may be applied to various algorithms for improving image quality. The compensation value may include the optical compensation value. The register setting data may define operations of the data driving unit 306, the timing controller 303, the gamma compensation voltage generation unit 305, and the like. The first memory 301 may include a flash memory. The second memory 302 may include a static random-access memory (SRAM).

The host system 200 may be implemented as an application processor (AP). The host system 200 may transmit the pixel data of the input image to the driver IC 300 through a mobile industry processor interface (MIPI). The host system 200 may be connected to the driver IC 300 through a flexible printed circuit, for example, a flexible printed circuit (FPC).

Meanwhile, the display panel may be implemented as a flexible panel applicable to a flexible display. The flexible display may have a screen that varies in size by rolling, folding, or bending the flexible panel and may be easily manufactured with various designs.

The flexible display may be implemented as a rollable display, a foldable display, a bendable display, a slidable display, or the like.

The flexible panel may be manufactured as a so-called a “plastic OLED panel.” The plastic OLED panel may include a back plate and a pixel array formed on an organic thin film adhered to the back plate. A touch sensor array may be formed on the pixel array.

The back plate may be a polyethylene terephthalate (PET) substrate. The pixel array and the touch sensor array may be formed on the organic thin film. The back plate may block the permeation of moisture to the organic thin film so that the pixel array is not exposed to moisture.

The organic thin film may be a polyimide (PI) substrate. A multilayer buffer film may be formed of an insulating material (not shown) on the organic thin film. The circuit layer 12 and the light-emitting element layer 14 may be stacked on the organic thin film.

In the display device of the present disclosure, the pixel circuit and the gate driving unit disposed on the circuit layer 12 may include a plurality of transistors. The transistors may be implemented as oxide thin-film transistors (TFTs) including an oxide semiconductor, low-temperature polysilicon (LTPS) TFTs including LTPS, and the like. Each of the transistors may be implemented as a p-channel thin-film transistor (TFT) or an n-channel TFT. The following embodiments will be described focusing on an example in which the transistors of the pixel circuit are implemented as p-channel TFTs, but the present disclosure is not limited thereto.

The transistor is a three-electrode element including a gate, a source, and a drain. The source is an electrode that provides carriers to the transistor. The carriers in the transistor may start to flow from the source. The drain is an electrode through which the carriers exit from the transistor to the outside.

In the transistor, carriers flow from the source to the drain. In the case of an n-channel transistor, carriers are electrons, and thus a source voltage is lower than a drain voltage so that the electrons flow from the source to the drain. In the n-channel transistor, current flows from the drain to the source.

In the case of a p-channel transistor (PMOS), carriers are holes, and thus a source voltage is higher than a drain voltage so that the holes flow from the source to the drain. In the p-channel transistor, since the holes flow from the source to the drain, current flows from the source to the drain. It should be noted that the source and the drain of the transistor are not fixed in position. For example, the source and the drain are interchangeable depending on the applied voltage. Accordingly, the present disclosure is not limited by the source and the drain of the transistor. In the following description, the source and the drain of the transistor will be referred to as a first electrode and a second electrode.

A gate pulse may swing between a gate-on voltage and a gate-off voltage. The gate-on voltage may be set to be higher than a threshold voltage of the transistor, and the gate-off voltage may be set to be lower than the threshold voltage of the transistor.

The transistor may be turned on in response to the gate-on voltage and turned off in response to the gate-off voltage. In the case of an n-channel transistor, the gate-on voltage may be a gate-high voltage VGH, and the gate-off voltage may be a gate-low voltage VGL. In the case of a p-channel transistor, the gate-on voltage may be a gate-low voltage VGL, and the gate-off voltage may be a gate-high voltage VGH.

The driving element of the pixel circuit may be implemented as a transistor. The driving element should have uniform electrical characteristics between all the pixels, but there may be differences in electrical characteristics between the pixels due to a process variation and an element characteristic variation, and the electrical characteristics may vary as a display driving time passes.

In order to compensate for the electrical characteristic variation of the driving element, the display device may include an internal compensation circuit and an external compensation circuit. The internal compensation circuit may be added to the pixel circuit in each of the subpixels to sample a threshold voltage Vth and/or a mobility u of the driving element, which vary according to the electrical characteristics of the driving element, and compensate for the variation in real time.

The external compensation circuit may transmit the threshold voltage and/or mobility of the driving element, which are sensed through the sensing line connected to each of the subpixels, to an external compensation unit. The compensation unit of the external compensation circuit may reflect the sensing result to modulate the pixel data of the input image, thereby compensating for the variation in the electrical characteristics of the driving element.

A voltage of the pixel, which varies according to electrical characteristics of an external compensation driving element, may be sensed, and data of an input image may be modulated in an external circuit based on the sensed voltage, thereby compensating for the variation in the electrical characteristics of the driving element between the pixels.

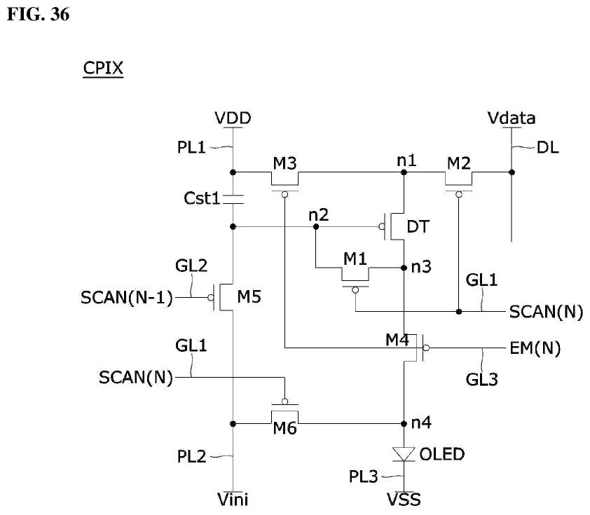

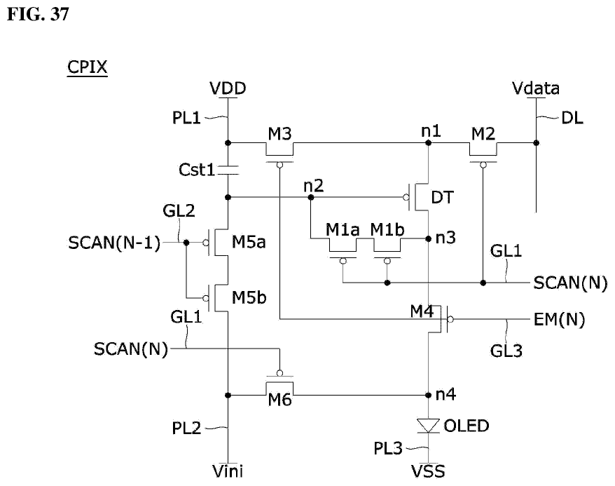

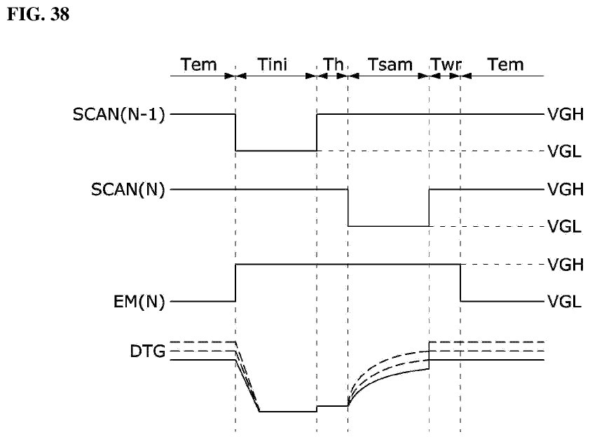

FIG. 36 is a circuit diagram illustrating an example of the pixel circuit, and FIG. 37 is a circuit diagram illustrating another example of the pixel circuit. FIG. 38 is a diagram illustrating a method of driving the pixel circuits shown in FIGS. 36 and 37 according to one embodiment.

The pixel circuits shown in FIGS. 36 and 37 may be similarly applied to the pixel circuit of the first display area DA and the second display area CA. The pixel circuit applicable to the present disclosure may be implemented as the circuits shown in FIGS. 36 and 37, but the present disclosure is not limited thereto.

Referring to FIGS. 36 to 38, the pixel circuit may include a light-emitting element OLED, a driving element DT configured to supply current to the light-emitting element OLED, and an internal compensation circuit configured to sample a threshold voltage Vth of the driving element DT using a plurality of switch elements M1 to M6 and compensate a gate voltage of the driving element DT by as much as the threshold voltage Vth of the driving element DT. Each of the driving element DT and the switch elements M1 to M6 may be implemented as a p-channel TFT.

A driving period of the pixel circuit using the internal compensation circuit may be divided into an initialization period Tini, a sampling period Tsam, a data writing period Twr, and a light emission period Tem, as shown in FIG. 38.

During the initialization period Tini, an N−1th scan signal SCAN(N−1) is generated as a pulse of a gate-on voltage VGL, and a voltage of each of an Nth scan signal SCAN(N) and an emission signal EM(N) is a gate-off voltage VGH. During the sampling period Tsam, the Nth scan signal SCAN(N) is generated as a pulse of the gate-on voltage VGL, and a voltage of each of the N−1th scan signal SCAN(N−1) and the emission signal EM(N) is the gate-off voltage VGH. During the data writing period Twr, a voltage of each of the N−1th scan signal SCAN(N−1), the Nth scan signal SCAN(N), and the emission signal EM(N) is the gate-off voltage VGH. During at least a partial period of the light emission period Tem, the emission signal EM(N) may be generated as the gate-on voltage VGL, and a voltage of each of the N−1th scan signal SCAN(N−1) and the Nth scan signal SCAN(N) may be generated as the gate-off voltage VGH.

During the initialization period Tini, a fifth switch element M5 may be turned on according to the gate-on voltage VGL of the N−1th scan signal SCAN(N−1) to initialize the pixel circuit. During the sampling period Tsam, first and second switch elements M1 and M2 may be turned on according to the gate-on voltage VGL of the Nth scan signal SCAN(N) so that the threshold voltage of the driving element DT may be sampled and stored in a storage capacitor Cst1. At the same time, a sixth switch element M6 may be turned on during the sampling period Tsam to lower a voltage of a fourth node n4 to a reference voltage Vref to suppress light emission of the light-emitting element OLED. During the data writing period Twr, the first to sixth switch elements M1 to M6 may be maintained in an OFF state. During the light emission period Tem, the third and fourth switch elements M3 and M4 may be turned on so that the light-emitting element OLED may emit light. In the light emission period Tem, in order to precisely express a luminance of a low grayscale with a duty ratio of the emission signal EM(N), the emission signal EM(N) may swing between the gate-on voltage VGL and the gate-off voltage VGH at a predetermined duty ratio to repeat turning the third and fourth switch elements M3 and M4 on or off.

The light-emitting element OLED may be implemented as an organic light-emitting diode or an inorganic light-emitting diode. Hereinafter, an example in which the light-emitting element OLED is implemented as an organic light-emitting diode will be described.

The light-emitting element OLED may include an organic compound layer formed between an anode and a cathode. The organic compound layer may include a hole injection layer HIL, a hole transport layer HTL, a light-emitting layer EML, an electron transport layer ETL, and an electron injection layer EIL, but the present disclosure is not limited thereto. When a voltage is applied to the anode and the cathode of the OLED, holes passing through the hole transport layer HTL and electrons passing through the electron transport layer ETL move to the emission layer EML to create excitons, and thus visible light may be emitted from the light-emitting layer EML.

The anode of the light-emitting element OLED is connected to the fourth node n4 between the fourth and sixth switch elements M4 and M6. The fourth node n4 is connected to the anode of the light-emitting element OLED, a second electrode of the fourth switch element M4, and a second electrode of the sixth switch element M6. The cathode of the light-emitting element OLED may be connected to the VSS line PL3 to which the low-potential power supply voltage VS S is applied. The light-emitting element OLED may emit light with a current Ids that flows according to a gate-source voltage Vgs of the driving element DT. The third and fourth switch elements M3 and M4 may switch current paths of the light-emitting element OLED.

The storage capacitor Cst1 may be connected between the VDD line PL1 and a first node n1. A data voltage Vdata, which is compensated by as much as the threshold voltage Vth of the driving element DT, may be charged to the storage capacitor Cst1. Since the data voltage Vdata in each sub-pixel is compensated by as much as the threshold voltage Vth of the driving element DT, a characteristic deviation of the driving element DT in each sub-pixel may be compensated for.

The first switch element M1 may be turned on in response to the gate-on voltage VGL of the Nth scan signal SCAN(N) to connect a second node n2 to a third node n3. The second node n2 may be connected to a gate electrode of the driving element DT, a first electrode of the storage capacitor Cst1, and a first electrode of the first switch element M1. The third node n3 may be connected to a second electrode of the driving element DT, a second electrode of the first switch element M1, and a first electrode of the fourth switch element M4. A gate electrode of the first switch element M1 is connected to a first gate line GL1 to receive the Nth scan signal SCAN(N). The first electrode of the first switch element M1 may be connected to the second node n2, and the second electrode thereof may be connected to the third node n3.

The first switch element M1 may be turned on only in one very short horizontal period 1H during which the Nth scan signal SCAN(N) is generated as the gate-on voltage VGL in one frame period and thus may be maintained in an OFF state for about one frame period, and thus a leakage current may be generated in the OFF state of the first switch element M1. In order to suppress the leakage current of the first switch element M1, the first switch element M1 may be implemented as a dual-gate structure transistor having two transistors M1a and M1b connected in series, as shown in FIG. 37.

The second switch element M2 may be turned on in response to the gate-on voltage VGL of the Nth scan signal SCAN(N) to supply the data voltage Vdata to the first node n1. A gate electrode of the second switch element M2 may be connected to the first gate line GL1 to receive the Nth scan signal SCAN(N). A first electrode of the second switch element M2 may be connected to the first node n1. A second electrode of the second switch element M2 may be connected to a data line DL to which the data voltage Vdata is applied. The first node n1 may be connected to the first electrode of the second switch element M2, a second electrode of the third switch element M3, and a first electrode of the driving element DT.

The third switch element M3 may be turned on in response to the gate-on voltage VGL of the emission signal EM(N) to connect the VDD line PL1 to the first node n1. A gate electrode of the third switch element M3 may be connected to a third gate line GL3 to receive the emission signal EM(N). A first electrode of the third switch element M3 may be connected to the VDD line PL1. The second electrode of the third switch element M3 may be connected to the first node n1.

The fourth switch element M4 may be turned on in response to the gate-on voltage VGL of the emission signal EM(N) to connect the third node n3 to the anode of the light-emitting element OLED. A gate electrode of the fourth switch element M4 may be connected to the third gate line GL3 to receive the emission signal EM(N). The first electrode of the fourth switch element M4 may be connected to the third node n3, and the second electrode thereof may be connected to the fourth node n4.

The fifth switch element M5 may be turned on in response to the gate-on voltage VGL of the N−1th scan signal SCAN(N−1) to connect the second node n2 to a Vini line PL2. A gate electrode of the fifth switch element M5 may be connected to a second gate line GL2 to receive the N−1th scan signal SCAN(N−1). A first electrode of the fifth switch element M5 may be connected to the second node n2, and a second electrode thereof may be connected to the Vini line PL2. In order to suppress a leakage current of the fifth switch element M5, the fifth switch element M5 may be implemented as a dual-gate structure transistor having two transistors M5a and M5b connected in series, as shown in FIG. 37.

The sixth switch element M6 may be turned on in response to the gate-on voltage VGL of the Nth scan signal SCAN(N) to connect the Vini line PL2 to the fourth node n4. A gate electrode of the sixth switch element M6 may be connected to the first gate line GL1 to receive the Nth scan signal SCAN(N). A first electrode of the sixth switch element M6 may be connected to the Vini line PL2, and the second electrode thereof may be connected to the fourth node n4.

The driving element DT may adjust the current Ids, which flows in the light-emitting element OLED according to the gate-source voltage Vgs, to drive the light-emitting element OLED. The driving element DT may include the gate electrode connected to the second node n2, the first electrode connected to the first node n1, and the second electrode connected to the third node n3.

As shown in FIG. 38, the N−1th scan signal SCAN(N−1) may be generated as the gate-on voltage VGL during the initialization period Tini. During the initialization period Tini, the Nth scan signal SCAN(N) and the emission signal EM(N) may each be maintained at the gate-off voltage VGH. Thus, during the initialization period Tini, the fifth switch element M5 may be turned on so that the second and fourth nodes n2 and n4 may each be initialized to “Vini.” A hold period Th may be set between the initialization period Tini and the sampling period Tsam. During the hold period Th, the gate signals SCAN(N−1), SCAN(N), and EM(N) may be maintained in previous states thereof.

During the sampling period Tsam, the Nth scan signal SCAN(N) may be generated as the gate-on voltage VGL. The Nth scan signal SCAN(N) may be synchronized with the data voltage Vdata of an Nth pixel line. During the sampling period Tsam, the N−1th scan signal SCAN(N−1) and the emission signal EM(N) may each be maintained at the gate-off voltage VGH. Thus, during the sampling period Tsam, the first and second switch elements M1 and M2 may be turned on.

During the sampling period Tsam, a gate voltage DTG of the driving element DT may rise due to a current flowing through the first and second switch elements M1 and M2. When the driving element DT is turned off, the gate voltage DTG is Vdata-|Vth|. In this case, the voltage of the first node n1 is also Vdata-|Vth|. During the sampling period Tsam, the gate-source voltage Vgs of the driving element DT is |Vgs|=Vdata−(Vdata−|Vth|)=|Vth|.

During the data writing period Twr, the Nth scan signal SCAN(N) may be inverted to the gate-off voltage VGH. During the data writing period Twr, the N−1th scan signal SCAN(N−1) and the emission signal EM(N) may each be maintained at the gate-off voltage VGH. Thus, during the data writing period Twr, all the switch elements M1 to M6 may be maintained in an OFF state.

During the light emission period Tem, the emission signal EM(N) may be generated as the gate-on voltage VGL. During the light emission period Tem, in order to improve low grayscale expression, the emission signal EM(N) may be turned on or off at a predetermined duty ratio to swing between the gate-on voltage VGL and the gate-off voltage VGH. Accordingly, the emission signal EM(N) may be generated as the gate-on voltage VGL for at least a partial period of the light emission period Tem.

When the emission signal EM(N) is at the gate-on voltage VGL, current flows between “VDD” and the light-emitting element OLED so that the light-emitting element OLED may emit light. During the light emission period Tem, the N−1th and Nth scan signals SCAN(N−1) and SCAN(N) may each be maintained at the gate-off voltage VGH. During the light emission period Tem, the third and fourth switch elements M3 and M4 may be repeatedly turned on and off according to the voltage of the emission signal EM(N). When the emission signal EM(N) is at the gate-on voltage VGL, the third and fourth switch elements M3 and M4 are turned on so that current flows in the light-emitting element OLED. In this case, “Vgs” of the driving element DT satisfies |Vgs|=VDD−(Vdata−|Vth|), and the current flowing in the light-emitting element OLED is K(VDD−Vdata)2. “K” is a constant determined by charge mobility, parasitic capacitance, and channel capacity of the driving element DT.

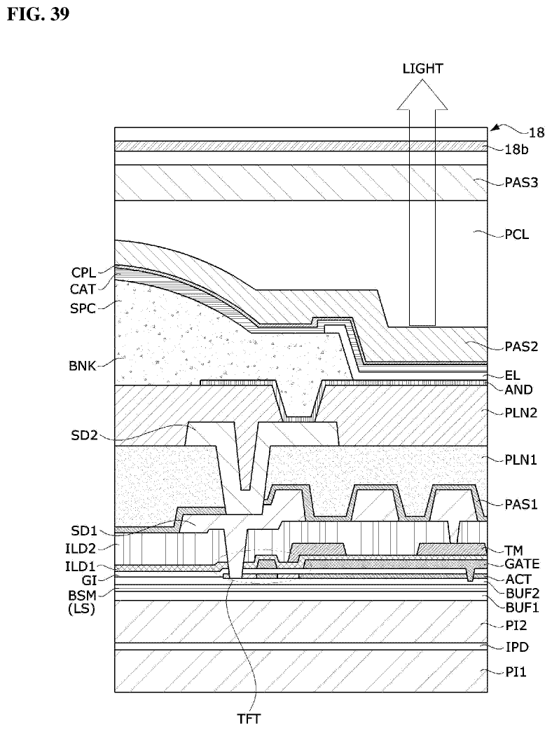

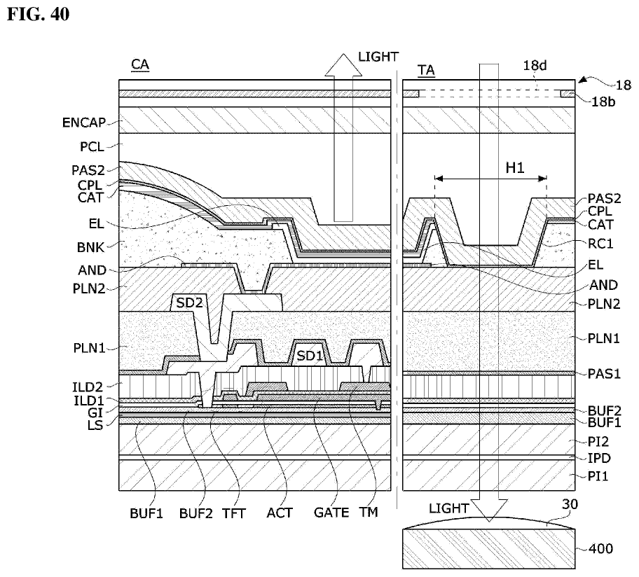

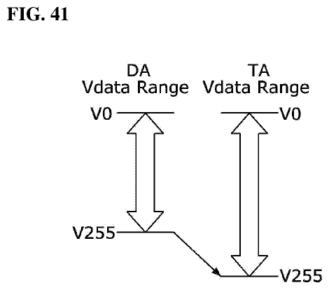

FIG. 39 is a cross-sectional view illustrating a cross-sectional structure of a pixel area in a display panel according to one embodiment of the present disclosure in detail, and FIG. 40 illustrates a cross-sectional structure of the pixel area and a light-transmitting area according to one embodiment of the present disclosure.

The cross-sectional structure of the display panel 100 is not limited to that in FIG. 39. In FIG. 39, “TFT” represents a driving element DT of the pixel circuit.

Referring to FIG. 39, a circuit layer, a light-emitting element layer, and the like may be stacked on substrates PI1 and PI2 in a pixel area PIX. The substrates PI1 and PI2 may include a first PI substrate PI1 and a second PI substrate PI2. An inorganic film IPD may be formed between the first PI substrate PI1 and the second PI substrate PI2. The inorganic film IPD may block the penetration of moisture.

A first buffer layer BUF1 may be formed on the second PI substrate PI2. A first metal layer may be formed on the first buffer layer BUF1, and a second buffer layer BUF2 may be formed on the first metal layer.

The first metal layer may be patterned by a photolithography process. The first metal layer may include a light shield pattern BSM. The light shield pattern BSM may block external light so that the light is not irradiated to an active layer of a TFT, thereby preventing or at least reducing a photo current of the TFT formed in the pixel area from being generated.

When the light shield pattern BSM is formed of a metal having a low absorption coefficient of a laser wavelength used in a laser ablation process as compared to a metal layer (e.g., a cathode) to be removed from the second display area CA, the light shield pattern BSM may also serve as a light shield layer LS configured to block a laser beam LB in the laser ablation process.

Each of the first and second buffer layers BUF1 and BUF2 may be made of an inorganic insulating material and may be formed of one or more insulating layers.

An active layer ACT may be made of a semiconductor material deposited on the second buffer layer BUF2 and may be patterned by a photolithography process. The active layer ACT may include an active pattern of each of TFTs of the pixel circuit and TFTs of the gate driving unit. A portion of the active layer ACT may be metallized by ion doping. The metallized portion may be used as a jumper pattern connecting the metal layers at some nodes of the pixel circuit to connect components of the pixel circuit.

A gate insulating layer G1 may be formed on the second buffer layer BUF2 so as to cover the active layer ACT. The gate insulating layer G1 may be made of an inorganic insulating material.

A second metal layer may be formed on the gate insulating layer G1. The second metal layer may be patterned by a photolithography process. The second metal layer may include a gate line, a gate electrode pattern GATE, a lower electrode of the storage capacitor Cst1, a jumper pattern connecting patterns of the first metal layer and a third metal layer, and the like.

A first interlayer insulating layer ILD1 may be formed on the gate insulating layer G1 so as to cover the second metal layer. The third metal layer may be formed on the first interlayer insulating layer ILD1, and a second interlayer insulating layer ILD2 may cover the third metal layer. The third metal layer may be patterned by a photolithography process. The third metal layer may include metal patterns TM, such as an upper electrode of the storage capacitor Cst1. The first and second interlayer insulating layers ILD1 and ILD2 may each include an inorganic insulating material.

A fourth metal layer may be formed on the second interlayer insulating layer ILD2, and an inorganic insulating layer PAS1 and a first planarization layer PLN1 may be stacked on the fourth metal layer. A fifth metal layer may be formed on the first planarization layer PLN1.

Some patterns of the fourth metal layer may be connected to the third metal layer through a contact hole passing through the first planarization layer PLN1 and the inorganic insulating layer PAS1. The first and second planarization layers PLN1 and PLN2 may each be made of an organic insulating material enabling surfaces thereof to be flat.

The fourth metal layer may include first and second electrodes of a TFT connected to an active pattern of the TFT through a contact hole passing through the second interlayer insulating layer ILD2. The data line DL and the power lines may be implemented using a pattern SD1 of the fourth metal layer or a pattern SD2 of the fifth metal layer.

An anode AND, which is a first electrode layer of the light-emitting element OLED, may be formed on the second planarization layer PLN2. The anode AND may be connected to an electrode of a TFT used as the switch element or the driving element through a contact hole passing through the second planarization layer PLN2. The anode AND may be made of a transparent or semitransparent electrode material.

A pixel-defining film BNK may cover the anode AND of the light-emitting element OLED. The pixel-defining film BNK may be formed in a pattern that defines an emission area (or an opening area) through which light passes to the outside from each of the pixels. A spacer SPC may be formed on the pixel-defining film BNK. The pixel-defining film BNK and the spacer SPC may be integrated with the same organic insulating material. The spacer SPC may secure a gap between a fine metal mask (FMM) and the anode AND so that the FMM is not in contact with the anode AND in a deposition process of an organic compound EL.

The organic compound EL may be formed in the emission area of each of the pixels, which is defined by the pixel-defining film BNK. A cathode CAT, which is a second electrode layer of the light-emitting element OLED, may be formed on the entire surface of the display panel 100 so as to cover the pixel-defining film BNK, the spacer SPC, and the organic compound EL. The cathode CAT may be connected to the VSS line PL3 formed of any one of the metal layers therebelow. A capping layer CPL may cover the cathode CAT. The capping layer CPL may be made of an inorganic insulating material to block the penetration of the air and gas outgassed from the organic insulating material, which is applied on the capping layer CPL, to protect the cathode CAT. An inorganic insulating layer PAS2 may cover the capping layer CPL, and a planarization layer PCL may be formed on the inorganic insulating layer PAS2. The planarization layer PCL may include an organic insulating material. An inorganic insulating layer PAS3 of the encapsulation layer may be formed on the planarization layer PCL.

A polarizing plate 18 may be disposed on the inorganic insulating layer PAS3 to improve the outdoor visibility of the display device. The polarizing plate 18 may reduce the reflection of light from a surface of the display panel 100 and block the light reflected from metal of the circuit layer 12, thereby improving the brightness of the pixels.

Referring to FIG. 40, a partial area of each of the anode AND and the light-emitting element EL disposed in the second display area CA may extend to the light-transmitting area TA. Thus, the luminance of the light-transmitting area TA may be increased and uniform image quality may be realized.

Further, in the light-transmitting area TA, a first light-transmitting pattern 18d may be formed in the polarizing plate 18. The first light-transmitting pattern 18d may be formed by discoloring a polarizer 18b using a laser, or the first light-transmitting pattern 18d may be formed by partially removing the polarizer 18b.

In the light-transmitting area TA, an opening H1 may be formed in the cathode CAT. The opening H1 may be formed by forming the cathode CAT on the pixel-defining film BNK and then etching the cathode CAT and the pixel-defining film BNK at one time. Accordingly, a first groove RC1 may be formed in the pixel-defining film BNK, and the opening H1 of the cathode CAT may be formed on the first groove RC1. However, the present disclosure is not necessarily limited thereto, and the cathode CAT may be disposed on the second planarization layer PLN2 without forming the pixel-defining film in the light-transmitting area TA.

In the light-transmitting area TA, the first light-transmitting pattern 18d is formed in the polarizing plate 18, and the opening H1 is formed in the cathode so that light transmittance may be improved. Thus, a sufficient amount of light may be introduced into the camera module 400 so that camera performance may be improved. In addition, noise of imaged image data may be reduced.

FIG. 41 is a view illustrating a data voltage applied to the pixels of the first display area and a data voltage applied to the pixels of the second display area.

Referring to FIG. 41, since the PPI of the second display area CA is relatively lower than that of the first display area DA, the data driving unit may enlarge the range of the data voltage Vdata applied to the pixels of the second display area CA as compared to the range of the data voltage Vdata applied to the pixels of the first display area DA.

According to embodiments, the quality of a picture in an imaging area can be improved. In addition, data noise of an image captured in a state in which light transmittance is increased can be reduced so that camera performance can be improved.

Effects of the present disclosure will not be limited to the above-mentioned effects and other unmentioned effects will be clearly understood by those skilled in the art from the following claims.

It will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. A display device comprising:
a first display area including a plurality of first pixel groups; and
a second display area including a plurality of second pixel groups and a plurality of light-transmitting areas,
wherein each of the plurality of second pixel groups includes a plurality of sub-pixels, and
wherein in any one sub-pixel of the plurality of sub-pixels, a light-emitting element is disposed in a light-transmitting area from the plurality of light-transmitting areas that corresponds to the any one sub-pixel.

2. The display device of claim 1, wherein the second display area includes a first pixel row in which the plurality of second pixel groups are continuously disposed in a first direction, and a second pixel row in which the plurality of light-transmitting areas are continuously disposed in the first direction,
wherein the first pixel row and the second pixel row are alternately disposed in a second direction intersecting the first direction.

3. The display device of claim 2, wherein the plurality of sub-pixels include a first sub-pixel including a first light-emitting element, a second sub-pixel including a second light-emitting element, a third sub-pixel including a third light-emitting element, and a fourth sub-pixel including a fourth light-emitting element,
wherein a partial area of at least one of the second light-emitting element and the fourth light-emitting element is disposed in the light-transmitting area.

4. The display device of claim 3, wherein the second light-emitting element and the fourth light-emitting element are green light-emitting elements.

5. The display device of claim 3, wherein a first imaginary line connecting a center of each of the second light-emitting element and the fourth light-emitting element intersects the first direction and the second direction.

6. The display device of claim 5, wherein each of the plurality of first pixel groups includes a first green light-emitting element and a second green light-emitting element,
wherein an imaginary line connecting a center of each of the first green light-emitting element and the second green light-emitting element is parallel to the first direction.

7. The display device of claim 3, wherein, based on a second imaginary line passing through a center of each of the first light-emitting element and the third light-emitting element,
the second light-emitting element is disposed on one side of the second imaginary line, and
the fourth light-emitting element is disposed on another side of the second imaginary line.

8. The display device of claim 3, wherein the first light-emitting element to the fourth light-emitting element of the plurality of second pixel groups have a structure in which light-emitting elements of a same color are disposed in a quadrangular shape.

9. The display device of claim 3, wherein fourth light-emitting elements of the plurality of second pixel groups are disposed along each of a plurality of quadrangular-shaped lines, and
wherein the first light-emitting element, the second light-emitting element, and the third light-emitting element are disposed inside each of the plurality of quadrangular-shaped lines.

10. The display device of claim 1, wherein a resolution of the second display area is less than a resolution of the first display area.

11. The display device of claim 1, further comprising lines disposed in the first display area and the second display area,
wherein the lines are disposed to bypass the light-transmitting areas.

12. The display device of claim 1, comprising a cathode disposed in the first display area and the second display area,
wherein the cathode includes an opening corresponding to the plurality of light-transmitting area.

13. The display device of claim 1, wherein a shape of light-emitting elements of the first pixel group is different from a shape of light-emitting elements of the second pixel group.

14. A display device comprising:
a first display area including a plurality of first pixel groups; and
a second display area including a plurality of second pixel groups and a plurality of light-transmitting areas,
wherein the plurality of second pixel groups include a plurality of sub-pixels,
wherein the plurality of second pixel groups include a first light-emitting element configured to emit red light, a third light-emitting element configured to emit blue light, and a second light-emitting element and a fourth light-emitting element configured to emit green light, and
a first imaginary line connecting a center of each of the second light-emitting element and the fourth light-emitting element intersects a second imaginary line connecting a center of each of the first light-emitting element and the third light-emitting element.

15. The display device of claim 14, wherein, based on the second imaginary line,
the second light-emitting element is disposed on one side of the second imaginary line, and
the fourth light-emitting element is disposed on another side of the second imaginary line.

16. The display device of claim 14, wherein the second display area includes a first pixel row in which the plurality of second pixel groups are continuously disposed, and a second pixel row in which the plurality of light-transmitting areas are continuously disposed.

17. The display device of claim 14, wherein a portion of at least one of the second light-emitting element and the fourth light-emitting element is disposed in the light-transmitting area.

18. The display device of claim 14, wherein a number of the plurality of second pixel groups disposed in the second display area is less than a number of the plurality of first pixel groups disposed in the first display area.

19. A display device comprising:
a first display area including a plurality of first pixel groups; and
a second display area including a plurality of second pixel groups and a plurality of light-transmitting areas,
wherein the second display area includes a first unit area having less pixels than the first display area and a second unit area having less pixels than the first unit area.

20. The display device of claim 19, further comprising:
an image sensor disposed in the first unit area, and
an infrared sensor disposed in the second unit area.
